(19) United States
(12) Patent Application Publication
(10) Pub. No.: US 2025/0239550 A1
(43) Pub. Date: Jul. 24, 2025

(54) SEMICONDUCTOR DEVICE, SEMICONDUCTOR PACKAGE WITH REDISTRIBUTION LINE, AND METHOD OF FORMING SEMICONDUCTOR DEVICE

(71) Applicant: SK hynix Inc., Icheon-si Gyeonggi-do (KR)

(72) Inventors: Jae Yong AN, Icheon-si Gyeonggi-do (KR); Ju Heon YANG, Icheon-si Gyeonggi-do (KR); Kyo Sik YOON, Icheon-si Gyeonggi-do (KR)

(73) Assignee: SK hynix Inc., Icheon-si Gyeonggi-do (KR)

(21) Appl. No.: 19/006,565

(22) Filed: Dec. 31, 2024

Related U.S. Application Data
(63) Continuation-in-part of application No. 18/790,439, filed on Jul. 31, 2024.

(30) Foreign Application Priority Data
Jan. 18, 2024 (KR) 10-2024-0008174
Aug. 5, 2024 (KR) 10-2024-0103639

(51) Int. Cl. H01L 23/00

(52) U.S. Cl. CPC H01L 24/05; H01L 2224/02331; H01L 2224/0235; H01L 2224/0236; H01L 2224/0401; H01L 2224/04042

(57) ABSTRACT

A semiconductor device includes a chip body having a chip region and a residual scribe lane that surrounds the chip region; a passivation layer disposed on the chip region of the chip body; a first dielectric layer disposed on the passivation layer and the residual scribe lane of the chip body; a redistribution line disposed on the chip region of the first dielectric layer and including a wire bonding pad section; and a second dielectric layer disposed on the first dielectric layer and the redistribution line and having a first opening through which the wire bonding pad section is exposed.

### CROSS-REFERENCE TO RELATED APPLICATION

The present application is a continuation-in-part of pending U.S. patent application Ser. No. 18/790,439, filed on Jul. 31, 2024, which claims priority under 35 U.S.C. § 119 (a) to Korean Patent Application No. 10-2024-0008174 filed in the Korean Intellectual Property Office on Jan. 18, 2024, and claims priority under 35 U.S.C. § 119 (a) to Korean Patent Application No. 10-2024-0103639 filed in the Korean Intellectual Property Office on Aug. 5, 2024, which applications are incorporated herein by reference in their entirety.

### BACKGROUND

### 1. Technical Field

The present application generally relate to a semiconductor device, a semiconductor package with a redistribution line, and a method of forming a semiconductor device.

### 2. Related Art

A semiconductor device includes an integrated circuit that stores or processes data and has a chip pad through which data is input to the integrated circuit or output from the integrated circuit to outside.

The semiconductor device may include a redistribution line (RDL) pattern. The redistribution line is electrically connected to the chip pad and extends from a region where the chip pad is disposed to another region. The redistribution line substantially extends the chip pad to a connection point with an electrical connection member such as a wire and/or a bump. By using the redistribution line, the electrical connection point where the connection member is connected to the semiconductor device is changed to a location separated or distant from the location of the chip pad.

### SUMMARY

In an embodiment, a semiconductor device may include: a chip body having a chip region and a residual scribe lane that surrounds the chip region; a passivation layer disposed on the chip region of the chip body; a first dielectric layer disposed on the passivation layer and the residual scribe lane of the chip body; a redistribution line disposed on the chip region of the first dielectric layer and including a wire bonding pad section; and a second dielectric layer disposed on the first dielectric layer and the redistribution line and having a first opening through which the wire bonding pad section is exposed.

In an embodiment, a semiconductor package may include: a first semiconductor device including a chip body having a chip region and a residual scribe lane that surrounds the chip region, a passivation layer disposed on the chip region, a first dielectric layer covering the passivation layer and the residual scribe lane, a redistribution line disposed on the chip region of the first dielectric layer and including a wire bonding pad section and a bump bonding pad section, and a second dielectric layer disposed on the first dielectric layer and the redistribution line and having a first opening through which the wire bonding pad section is exposed and a second opening through which the bump bonding pad section is exposed; a second semiconductor device including a second semiconductor chip and a conductive bump connected to the second semiconductor chip, and stacked on the first semiconductor device such that the conductive bump is bonded to the bump bonding pad section of the redistribution line; a package substrate including a first substrate pad and supporting the first semiconductor device and the second semiconductor device; and a metal wire having a first end connected to the upper substrate pad and a second end connected to the wire bonding pad section.

In an embodiment, a method of manufacturing a semiconductor device may include: fabricating a wafer having a chip region in which a chip pad is disposed and a scribe lane that surrounds the chip region and includes a passivation layer that covers the chip region and through which the chip pad is exposed; forming a pre-first dielectric layer covering the passivation layer and the scribe lane of the wafer; forming, on the chip region of the pre-first dielectric layer, a redistribution line having a wire bonding pad section; forming a second dielectric layer, having a first opening through which the wire bonding pad section is exposed, and disposed on the redistribution line and the chip region of the pre-first dielectric layer; and dicing the wafer and the pre-first dielectric layer along the scribe lane.

In an embodiment, a semiconductor device may include: a semiconductor chip including a chip region and a residual scribe lane that surrounds the chip region, and having a passivation layer disposed on the chip region; a first dielectric layer covering the passivation layer and the residual scribe lane; a redistribution line disposed on the first dielectric layer and including a wire bonding pad section; and a second dielectric layer disposed on the first dielectric layer and the redistribution line and having a first opening through which the wire bonding pad section is exposed.

In an embodiment, a semiconductor device may include a passivation layer disposed on the chip region of the semiconductor device; a first dielectric layer disposed on the passivation layer and a residual scribe lane that surrounds the chip region; a redistribution line disposed on the first dielectric layer; and a second dielectric layer disposed on the first dielectric layer and the redistribution line and having a first opening through which a wire bonding pad of the redistribution line is exposed.

### BRIEF DESCRIPTION OF THE DRAWINGS

FIG. 1 is a plan view of a semiconductor device according to an embodiment of the present application.

FIG. 2 is a cross-sectional view of an embodiment of the semiconductor device taken along a line A-A′ of FIG. 1 according to an embodiment of the present application.

FIG. 3 is an enlarged plan view illustrating a redistribution line and a first dielectric layer of the semiconductor device according to an embodiment of the present application.

FIG. 4 is a cross-sectional view of an embodiment of the semiconductor device taken along a line B-B′ of FIG. 3 according to an embodiment of the present application.

FIG. 5 is a cross-sectional view of an embodiment of the semiconductor device taken along a line C-C′ of FIG. 3 according to an embodiment of the present application.

FIG. 6 is a cross-sectional view of an embodiment of the semiconductor device taken along a line D-D′ of FIG. 3 according to an embodiment of the present application.

FIG. 7 is a cross-sectional view of an embodiment of the semiconductor device taken along a line E-E′ of FIG. 3 according to an embodiment of the present application.

FIG. 8, FIG. 9, FIG. 10, FIG. 11, FIG. 12, and FIG. 13 are views illustrating a semiconductor device formed utilizing a method of forming the semiconductor device according to an embodiment of the present application.

FIG. 14 is a cross-sectional view of a semiconductor package according to an embodiment of the present application.

FIG. 15 is a plan view of a semiconductor device according to an embodiment of the present application.

FIG. 16 is a cross-sectional view of a semiconductor device taken along a line F-F′ of FIG. 15 according to an embodiment of the present application.

FIG. 17 to FIG. 21 are views illustrating a semiconductor device formed utilizing a method of forming the semiconductor device according to an embodiment of the present application.

FIG. 22 is a cross-sectional view of a semiconductor package according to an embodiment of the present application.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” or “under” another element, the elements may directly contact each other or an intervening element may be disposed between the elements.

Terms such as “vertical,” “horizontal,” “top,” “bottom,” “under,” “underlying,” “over,” “on,” “side,” “upper,” “lower,” “column,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Various embodiments of the present application are directed to providing a semiconductor device and a semiconductor package with a redistribution line and a redistribution line having a wire bonding pad and a method of forming a semiconductor package.

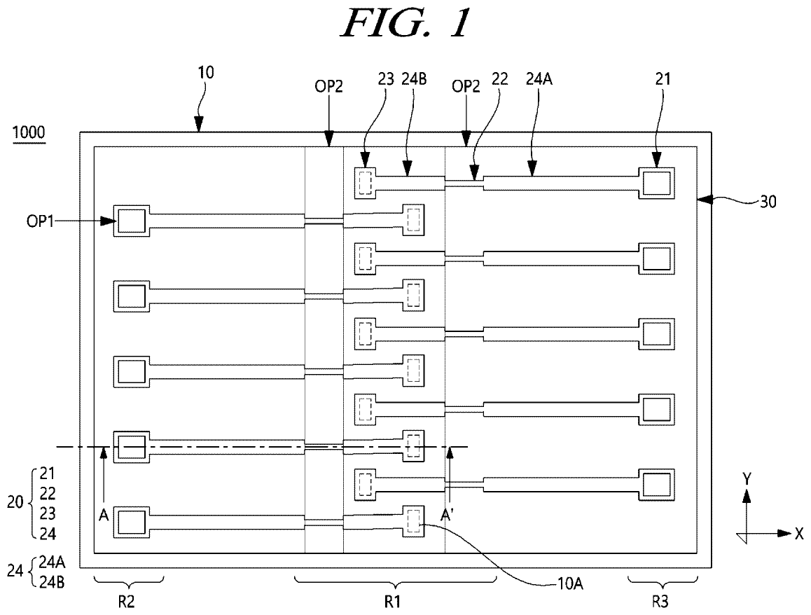

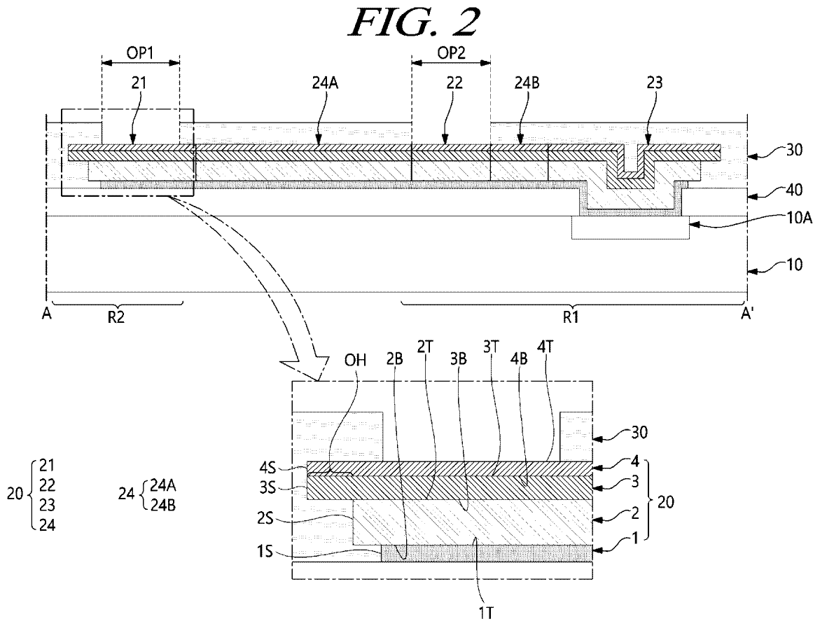

FIG. 1 is a plan view of a semiconductor device according to an embodiment of the present application, and FIG. 2 is a cross-sectional view of an embodiment taken along a line A-A′ of FIG. 1.

Referring to FIG. 1 and FIG. 2, the semiconductor device 100 according to an embodiment of the present application may include a semiconductor chip 10, a plurality of redistribution lines 20, and a first dielectric layer 30.

An integrated circuit (not illustrated) including cell transistors may be integrated into the semiconductor chip 10. The semiconductor chip 10 has a plurality of chip pads 10A. The chip pads 10A may be electrically connected to the integrated circuit through interconnection patterns (not illustrated) inside the semiconductor chip 10. The chip pads 10A are provided as connection terminals that electrically connect the semiconductor chip 10 to an external device.

The chip pads 10A may be disposed in a first region R1 of the semiconductor chip 10. The first region R1 may be the center region of the semiconductor chip 10 in the X-axis direction of an X-Y plane. The semiconductor chip 10 may be a center pad type semiconductor chip. The chip pads 10A may be disposed in two columns in the Y-axis direction of the X-Y plane in the first region R1 of the semiconductor chip 10. The present application is not limited to this example, and the arrangement of the chip pads 10A may be changed in various ways. A second region R2 and a third region R3 in FIG. 1 as both edge regions of the semiconductor chip 10 in the X-axis direction may be spaced apart from the first region R1 in the X-axis direction.

The semiconductor chip 10 may include a nonvolatile memory such as a NAND flash memory, a NOR flash memory, a PRAM (phase change random access memory) and an MRAM (magneto-resistive random access memory), a volatile memory such as a DRAM (dynamic random access memory) and an SRAM (static random access memory), and a processor such as a CPU (central processing unit), a GPU (graphics processing unit), an AP (application processor) and an NPU (neural processing unit), and so forth.

The redistribution lines 20 may be disposed on the semiconductor chip 10. The redistribution lines 20 may extend from the first region R1 to the second region R2 or the third region R3 of the semiconductor chip 10. As illustrated in FIG. 1, among ten redistribution lines 20, five redistribution lines 20 extend from the first region R1 to the second region R2, and five redistribution lines 20 extend from the first region R1 to the third region R3.

Each redistribution line 20 may include a wire bonding pad section 21, a bump bonding pad section 22, an overlapping pad section 23, and trace sections 24 connected together.

The wire bonding pad sections 21 of the redistribution lines 20 may be disposed on the second region R2 and the third region R3 of the semiconductor chip 10. For example, as shown in FIG. 1, the wire bonding pad sections 21 of five redistribution lines 20 among the ten redistribution lines 20 are disposed on the second region R2, and the wire bonding pad sections 21 of five redistribution lines 20 are disposed on the third region R3. The overlapping pad sections 23 of the redistribution lines 20 may be disposed on the first region R1 of the semiconductor chip 10. The bump bonding pad sections 22 of the redistribution lines 20 may be disposed to be spaced apart from the overlapping pad sections 23 on the first region R1 of the semiconductor chip 10.

The overlapping pad sections 23 of the redistribution lines 20 may overlap the chip pads 10A of the semiconductor chip 10. The overlapping pad section 23 is electrically connected to the chip pad 10A, and the trace sections 24, the wire bonding pad section 21 and the bump bonding pad section 22 are connected to the overlapping pad section 23. The redistribution line 20 may extend from the chip pad 10A that is disposed in the first region R1 of the semiconductor chip 10 to the second region R2 or the third region R3 where the wire bonding pad section 21 is disposed.

The overlapping pad sections 23 of the redistribution lines 20 may be disposed in two columns in the Y-axis direction on the first region R1 of the semiconductor chip 10. The present application is not limited to this example, and the arrangement of the overlapping pad sections 23 may vary depending on the arrangement of the chip pads 10A.

The wire bonding pad sections 21 of the redistribution lines 20 may be disposed in the Y-axis direction on the second region R2 and the third region R3 of the semiconductor chip 10. As illustrated in FIG. 1, the wire bonding pad sections 21 of five redistribution lines 20 among the ten redistribution lines 20 are disposed in one column in the Y-axis direction on the second region R2, and the wire bonding pad sections 21 of five redistribution lines 20 are disposed in one column in the Y-axis direction on the third region R3. As illustrated in FIG. 1, the bump bonding pad sections 22 of the redistribution lines 20 may be disposed in two columns in the Y-axis direction on the first region R1 of the semiconductor chip 10. The bump bonding pad sections 22 of the redistribution lines 20 may be disposed by being offset in the X-axis direction with respect to the chip pads 10A of the semiconductor chip 10.

The trace sections 24 of the redistribution line 20 may include a first trace section 24A and a second trace section 24B. The first trace section 24A may connect the wire bonding pad section 21 and the bump bonding pad section 22, and the second trace section 24B may connect the bump bonding pad section 22 and the overlapping pad section 23.

The wire bonding pad section 21 is connected to one end of the first trace section 24A, and may have a larger width than the first trace section 24A.

The bump bonding pad section 22 may be connected between the other end of the first trace section 24A opposite to the one end of the first trace section 24A and one end of the second trace section 24B. In FIG. 1, the first and second trace sections 24A and 24B have a constant width and the bump bonding pad section 22 has a smaller width compared to the first and second trace sections 24A and 24B, although the present application is not limited to this example. The width of the first and second trace sections 24A and 24B might not be constant, and the width of the bump bonding pad section 22 may have a size that is smaller than a maximum width and larger than a minimum width of the first and second trace sections 24A and 24B.

The overlapping pad section 23 may be connected to the other end of the second trace section 24B opposite to the one end of the second trace section 24B, and may have a larger width compared to the second trace section 24B.

A second dielectric layer 40 having openings that expose the chip pads 10A may be disposed on the semiconductor chip 10. The second dielectric layer 40 may cover the top surface of the semiconductor chip 10, and may expose the chip pads 10A. The second dielectric layer 40 may electrically isolate the redistribution lines 20 from the semiconductor chip 10. The second dielectric layer 40 may include a photosensitive polymer material such as polyimide.

The redistribution line 20 may be disposed on the second dielectric layer 40 and the chip pad 10A exposed by the opening of the second dielectric layer 40. The redistribution line 20 may be configured to include an electrically conductive layer 2, a barrier metal layer 3 on the electrically conductive layer 2, and a bonding metal layer 4 on the barrier metal layer 3. The redistribution line 20 may further include a base metal layer 1 under the electrically conductive layer 2.

The base metal layer 1 may be disposed on the surface of the second dielectric layer 40 and the surface of the chip pad 10A. The base metal layer 1 may be disposed between the electrically conductive layer 2 and the second dielectric layer 40. The base metal layer 1 may be extended to be disposed between the electrically conductive layer 2 and the chip pad 10A. The base metal layer 1 may contact the chip pad 10A of the semiconductor chip 10, and may electrically connect the chip pad 10A and the electrically conductive layer 2.

The base metal layer 1 may adhere to the second dielectric layer 40, the chip pad 10A and the electrically conductive layer 2. The base metal layer 1 may suppress a metal included in the electrically conductive layer 2 from diffusing to the semiconductor chip 10. The base metal layer 1 may provide the base of the redistribution line 20. The base metal layer 1 may include titanium (Ti) or titanium tungsten (TiW). The base metal layer 1 may be a titanium layer.

The electrically conductive layer 2 may be disposed on a top surface 1T of the base metal layer 1. The electrically conductive layer 2 includes a bottom surface 2B that faces the top surface 1T of the base metal layer 1, a top surface 2T opposite to the bottom surface 2B, and a side surface 2S that connects the edge of the bottom surface 2B and the edge of the top surface 2T. The outer peripheral section of the electrically conductive layer 2 has an overhang structure that is not supported by the underlying base metal layer 1. The outer peripheral section of the electrically conductive layer 2 has the overhang structure that is continuous along a side surface 1S of the base metal layer 1. The side surface 2S of the electrically conductive layer 2 may protrude beyond the side surface 1S of the base metal layer 1. The electrically conductive layer 2 may include copper (Cu). The electrically conductive layer 2 may be a copper layer.

The barrier metal layer 3 is disposed on the top surface 2T of the electrically conductive layer 2. The barrier metal layer 3 includes a bottom surface 3B that faces the top surface 2T of the electrically conductive layer 2, a top surface 3T opposite to the bottom surface 3B, and a side surface 3S that connects the edge of the bottom surface 3B and the edge of the top surface 3T.

The bonding metal layer 4 may include gold. When bonding a solder to the bump bonding pad section 22, the gold of the bonding metal layer 4 may disappear by diffusing to the solder. In an embodiment, the copper of the electrically conductive layer 2 may diffuse to an interface with the solder, and accordingly, an intermetallic compound may be generated. The barrier metal layer 3 may suppress the copper of the electrically conductive layer 2 from diffusing to the interface with the solder to reduce the consumption of the copper of the electrically conductive layer 2 and prevent or mitigate a thick intermetallic compound from being generated. The barrier metal layer 3 may be made of a metal material that adheres to the copper of the electrically conductive layer 2 and the gold (Au) of the bonding metal layer 4. The barrier metal layer 3 may include nickel (Ni). The barrier metal layer 3 may be a nickel layer.

The barrier metal layer 3 has a flange section OH that protrudes beyond the side surface 2S of the electrically conductive layer 2. The flange section OH of the barrier metal layer 3 has an overhang structure that is not supported by the underlying electrically conductive layer 2. The flange section OH of the barrier metal layer 3 has the overhang structure that is continuous along the side surface 2S of the electrically conductive layer 2. The side surface 3S of the barrier metal layer 3 may protrude beyond the side surface 2S of the electrically conductive layer 2.

The bonding metal layer 4 is disposed on the top surface 3T of the barrier metal layer 3. The bonding metal layer 4 includes a bottom surface 4B that faces the top surface 3T of the barrier metal layer 3, a top surface 4T opposite to the bottom surface 4B, and a side surface 4S that connects the edge of the bottom surface 4B and the edge of the top surface 4T. As illustrated in FIG. 2, the side surface 4S of the bonding metal layer 4 may be aligned with the side surface 3S of the barrier metal layer 3, although the present application is not limited to this example.

The bonding metal layer 4 may include a metal capable of wire bonding. The bonding metal layer 4 may include gold (Au). The bonding metal layer 4 may be a gold layer.

The first dielectric layer 30 may be disposed on the second dielectric layer 40 and the redistribution lines 20. The first dielectric layer 30 may be extended on a top surface of the bonding metal layer 4 to expose the wire bonding pad section 23. The first dielectric layer 30 may protect the redistribution lines 20. The first dielectric layer 30 may include a photosensitive polymer material such as polyimide.

The first dielectric layer 30 covers the overlapping pad sections 23 and the trace sections 24 of the redistribution lines 20, and has openings OP1 and OP2 that expose the wire bonding pad sections 21 and the bump bonding pad sections 22 of the redistribution lines 20. The openings OP1 and OP2 include first openings OP1 that expose the wire bonding pad sections 21 and second openings OP2 that expose the bump bonding pad sections 22.

The first openings OP1 are provided to individually expose the wire bonding pad sections 21 of the redistribution lines 20. The first openings OP1 correspond one-to-one to the wire bonding pad sections 21, and each may expose a corresponding wire bonding pad section 21. Although not illustrated, a metal wire may be bonded to the surface of the wire bonding pad section 21 exposed by the first opening OP1 of the first dielectric layer 30. The metal wire may be connected to the wire bonding pad section 21, and may be electrically connected to the chip pad 10A via the first and second trace sections 24A and 24B and the bump bonding pad section 22.

As illustrated in FIG. 1, the second openings OP2 may be configured in the form of a line extending in the Y-axis direction to simultaneously expose the bump bonding pad sections 22 disposed in a line in the Y-axis direction. In correspondence to the arrangement structure of the bump bonding pad sections 22 disposed in two columns in the Y-axis direction, the second openings OP2 of two columns in the form of lines extending in the Y-axis direction may be configured in the first dielectric layer 30. A conductive bump may be bonded to the surface of the bump bonding pad section 22 exposed by the second opening OP2 of the first dielectric layer 30. The conductive bump may be connected to the bump bonding pad section 22, and may be electrically connected to the chip pad 10A via the second trace section 24B.

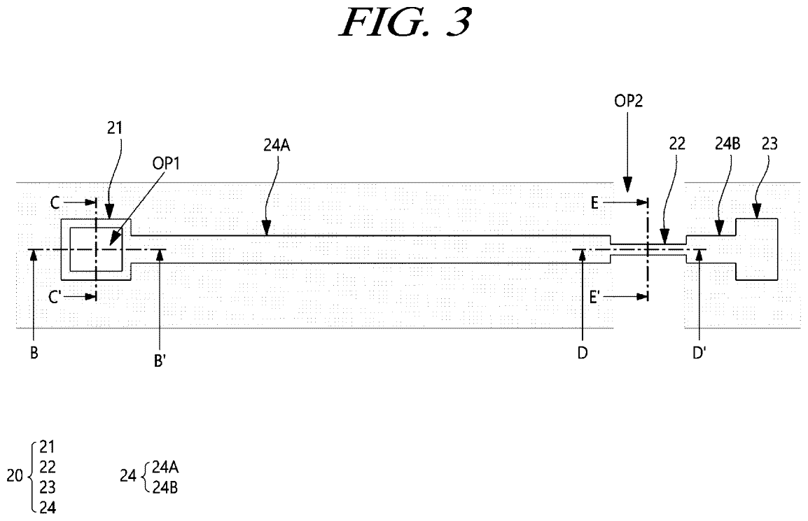

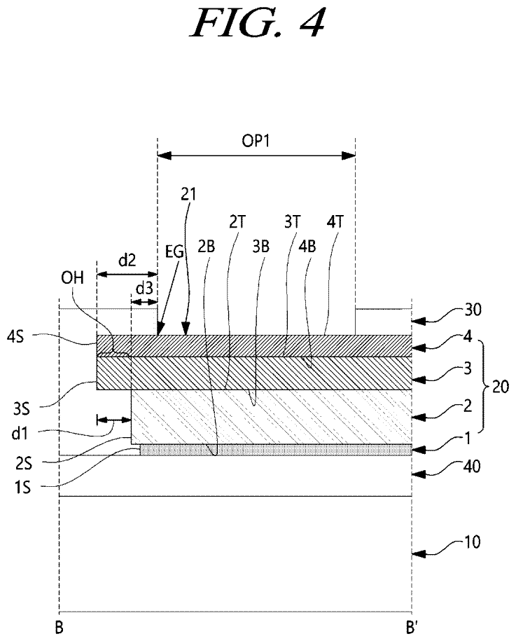

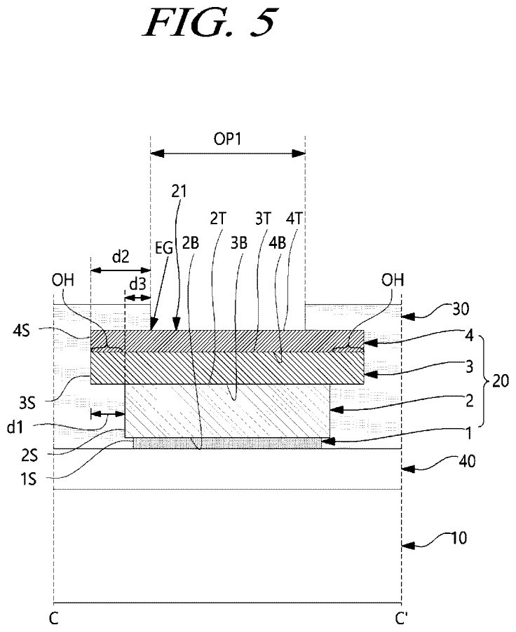

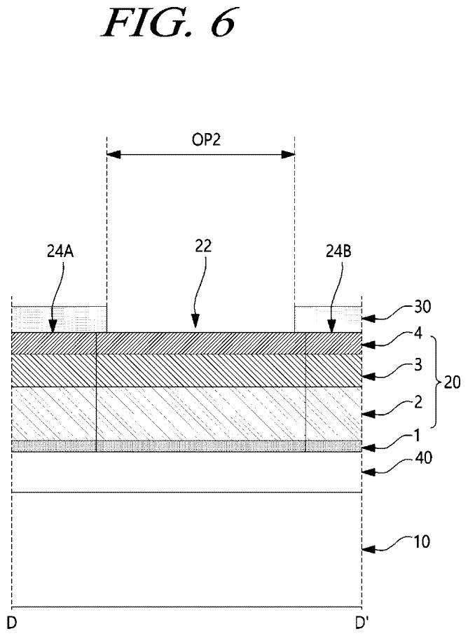

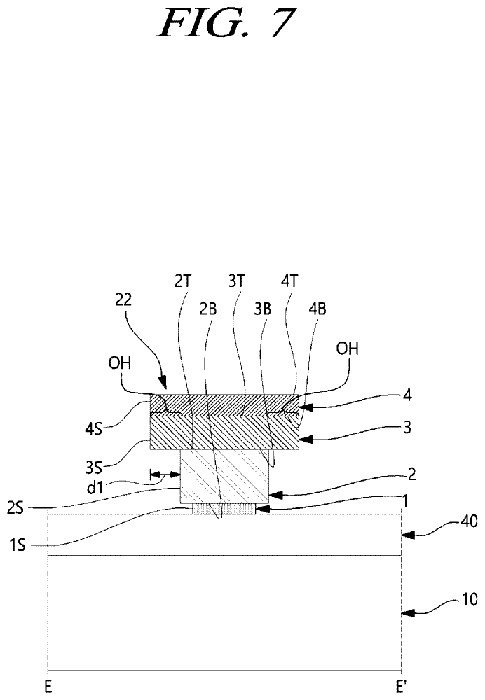

FIG. 3 is an enlarged plan view illustrating the redistribution line and the first dielectric layer of the semiconductor device according to an embodiment of the present application, FIG. 4 is a cross-sectional view taken along a line B-B′ of FIG. 3, FIG. 5 is a cross-sectional view taken along a line C-C′ of FIG. 3, FIG. 6 is a cross-sectional view taken along a line D-D′ of FIG. 3, and FIG. 7 is a cross-sectional view taken along a line E-E′ of FIG. 3.

Referring to FIG. 3 to FIG. 5, in the wire bonding pad section 21, the flange section OH of the barrier metal layer 3 protrudes beyond the side surface 2S of the electrically conductive layer 2. In the wire bonding pad section 21, the flange section OH of the barrier metal layer 3 has the overhang structure that is not supported by the underlying electrically conductive layer 2. The width of the flange section OH of the barrier metal layer 3 of the wire bonding pad section 21 may be d1. In the wire bonding pad section 21, the flange section OH of the barrier metal layer 3 has the overhang structure that is continuous along the side surface 2S of the electrically conductive layer 2.

In the wire bonding pad section 21, the side surface 3S of the barrier metal layer 3 may protrude beyond the side surface 2S of the underlying electrically conductive layer 2. In the wire bonding pad section 21, the side surface 3S of the barrier metal layer 3 may be spaced apart from the side surface 2S of the underlying electrically conductive layer 2 by a distance of d1. In the wire bonding pad section 21, the edge section of the bottom surface 3B of the barrier metal layer 3 that connects the side surface 3S of the barrier metal layer 3 and the side surface 2S of the electrically conductive layer 2 does not overlap the electrically conductive layer 2.

In the wire bonding pad section 21, the outer peripheral section of the electrically conductive layer 2 has the overhang structure that is not supported by the underlying base metal layer 1. In the wire bonding pad section 21, the outer peripheral section of the electrically conductive layer 2 has the overhang structure that is continuous along the side surface 1S of the base metal layer 1. In the wire bonding pad section 21, the side surface 2S of the electrically conductive layer 2 may protrude beyond the side surface 1S of the base metal layer 1.

The first dielectric layer 30 is provided to cover the side surface of the wire bonding pad section 21. The first dielectric layer 30 is provided to cover, in the wire bonding pad section 21, the side surface 4S of the bonding metal layer 4, the side surface 3S of the barrier metal layer 3, the side surface 2S of the electrically conductive layer 2 and the side surface 1S of the base metal layer 1. In addition, the first dielectric layer 30 is provided to cover, in the wire bonding pad section 21, the edge section of the bottom surface 3B of the barrier metal layer 3 between the side surface 2S of the electrically conductive layer 2 and the side surface 3S of the barrier metal layer 3.

In the wire bonding pad section 21, in an embodiment, the first dielectric layer 30 may cover the side surface 3S of the barrier metal layer 3 to prevent or mitigate a layer acting as a metal diffusion path from being generated. If the side surface 3S of the barrier metal layer 3 is exposed, as process byproducts combine with the exposed side surface 3S in a subsequent process, a metal inorganic compound may be formed. When the barrier metal layer 3 includes nickel, the metal inorganic compound may be nickel sulfide in which nickel combines with sulfur. The layer of the metal inorganic compound may provide a path through which the metal of the electrically conductive layer 2 moves. When the electrically conductive layer 2 includes copper, as the copper is ionized, the copper may diffuse to the bonding metal layer 4. In an embodiment, the diffused copper may be oxidized again to cause discoloration of the surface of the bonding metal layer 4 and hinder a metal wire from being bonded to the bonding metal layer 4. In an embodiment, because the first dielectric layer 30 suppresses the generation of the metal diffusion path, it is possible to suppress or prevent the occurrence of a defect in which the surface of the bonding metal layer 4 is discolored or a metal wire comes off without being bonded to the bonding metal layer 4.

The first dielectric layer 30 may extend to cover, in the wire bonding pad section 21, the edge section of the top surface 4T of the bonding metal layer 4. Accordingly, an edge EG of the first opening OP1 may be spaced apart from the side surface 4S of the bonding metal layer 4. As illustrated in FIG. 4, the edge EG of the first opening OP1 may be spaced apart from the side surface 4S of the bonding metal layer 4 by a distance of d2. The edge EG of the first opening OP1 may be disposed on the top surface 4T of the bonding metal layer 4, and the first dielectric layer 30 may continuously cover the edge section of the top surface 4T of the bonding metal layer 4 along the edge EG of the first opening OP1.

A metal wire may be bonded to the exposed section of the top surface 4T of the bonding metal layer 4 of the wire bonding pad section 21 exposed by the first opening OP1 of the first dielectric layer 30. The exposed section of the top surface 4T of the bonding metal layer 4 of the wire bonding pad section 21 exposed by the first opening OP1 may be a wire bonding area. The wire bonding area may be spaced apart, by a distance of d3, from the flange section OH of the barrier metal layer 3 that has the overhang structure. The distance d3 has a size corresponding to the difference between the distance d2 and the distance d1. The wire bonding area might not overlap the flange section OH of the barrier metal layer 3.

A metal element that forms the electrically conductive layer 2 may be ionized when exposed to moisture. When the electrically conductive layer 2 includes copper, the copper of the electrically conductive layer 2 may be ionized, and then, may diffuse to the wire bonding area along the surfaces of conductive layers disposed between the electrically conductive layer 2 and the wire bonding area.

According to an embodiment of the present application, by extending the first dielectric layer 30 to cover the edge section of the top surface 4T of the bonding metal layer 4 of the wire bonding pad section 21, it is possible to prevent or mitigate external moisture from penetrating into the electrically conductive layer 2, thereby suppressing the copper of the electrically conductive layer 2 from being ionized. According to an embodiment of the present application, by configuring the side surface 3S of the barrier metal layer 3 in the wire bonding pad section 21 to protrude beyond the side surface 2S of the underlying electrically conductive layer 2, the length of a path, that is, the length of a diffusion path, for the copper of the electrically conductive layer 2 to reach the wire bonding area may be increased. According to this fact, in an embodiment, it is possible to suppress or prevent the copper of the electrically conductive layer 2 from diffusing to the wire bonding area, and it is possible to suppress or prevent a defect such as discoloration of the wire bonding area and the coming-off of a metal wire.

Referring to FIG. 3, FIG. 6, and FIG. 7, in the bump bonding pad section 22, the flange section OH of the barrier metal layer 3 protrudes beyond the side surface 2S of the electrically conductive layer 2. In the bump bonding pad section 22, the flange section OH of the barrier metal layer 3 has the overhang structure that is not supported by the underlying electrically conductive layer 2. The flange section OH of the barrier metal layer 3 of the bump bonding pad section 22 has the overhang structure that is continuous along the side surface 2S of the electrically conductive layer 2. The width of the flange section OH of the barrier metal layer 3 of the bump bonding pad section 22 may be d1.

In the bump bonding pad section 22, the side surface 3S of the barrier metal layer 3 protrudes beyond the side surface 2S of the underlying electrically conductive layer 2. The side surface 3S of the barrier metal layer 3 of the bump bonding pad section 22 may be spaced apart from the side surface 2S of the underlying electrically conductive layer 2 by a distance of d1. In the bump bonding pad section 22, the edge section of the bottom surface 3B of the barrier metal layer 3 that connects the side surface 3S of the barrier metal layer 3 and the side surface 2S of the electrically conductive layer 2 does not overlap the electrically conductive layer 2.

In the bump bonding pad section 22, the outer peripheral section of the electrically conductive layer 2 has the overhang structure that is not supported by the base metal layer 1. In the bump bonding pad section 22, the outer peripheral section of the electrically conductive layer 2 has the overhang structure that is continuous along the side surface 1S of the base metal layer 1. In the bump bonding pad section 22, the side surface 2S of the electrically conductive layer 2 protrudes beyond the side surface 1S of the underlying base metal layer 1.

The second opening OP2 of the first dielectric layer 30 is provided to expose the bump bonding pad section 22. The second opening OP2 is provided to expose, in the bump bonding pad section 22, the top surface 4T and the side surface 4S of the bonding metal layer 4, the side surface 3S of the barrier metal layer 3, the side surface 2S of the electrically conductive layer 2, the edge section of the bottom surface 3B of the barrier metal layer 3 between the side surface 3S of the barrier metal layer 3 and the side surface 2S of the electrically conductive layer 2, and the side surface 1S of the base metal layer 1.

The bump bonding pad section 22 may be a structure to be coupled with a bump including a solder layer. In an embodiment, solder coupling is performed at a higher temperature than bonding wire coupling, and an intermetallic compound layer is thickly formed. Therefore, in an embodiment, copper oxide formed on the surface of the bump bonding pad section 22 might not have significant effect on bondability.

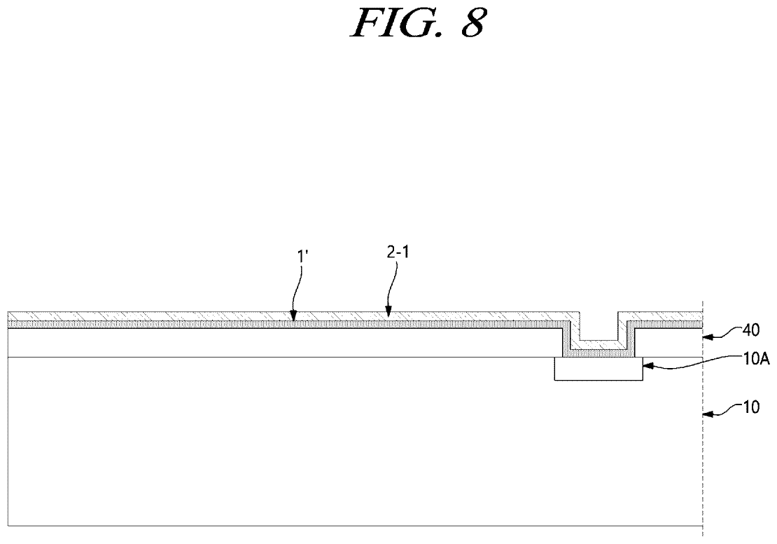

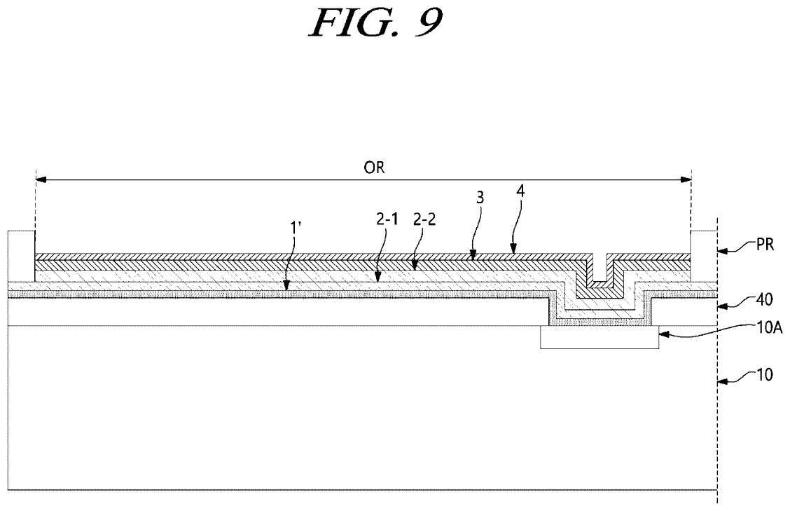

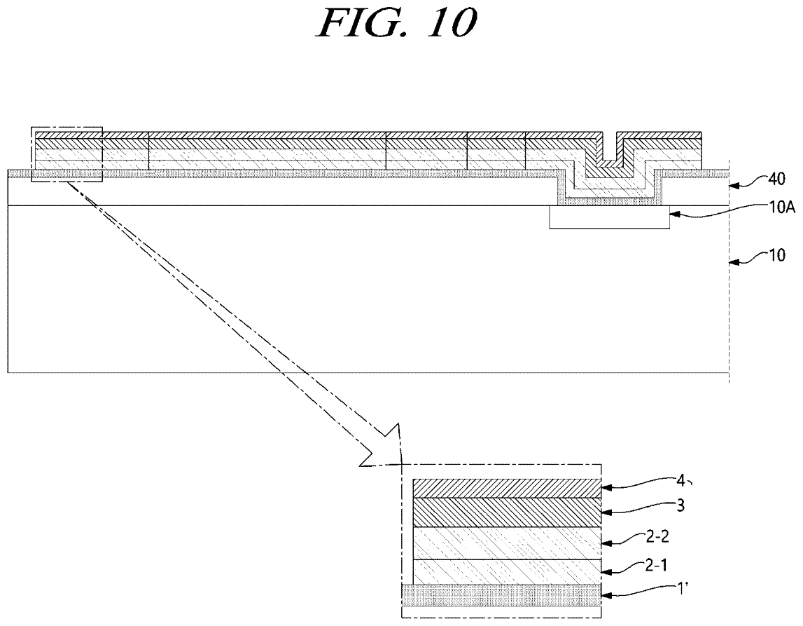

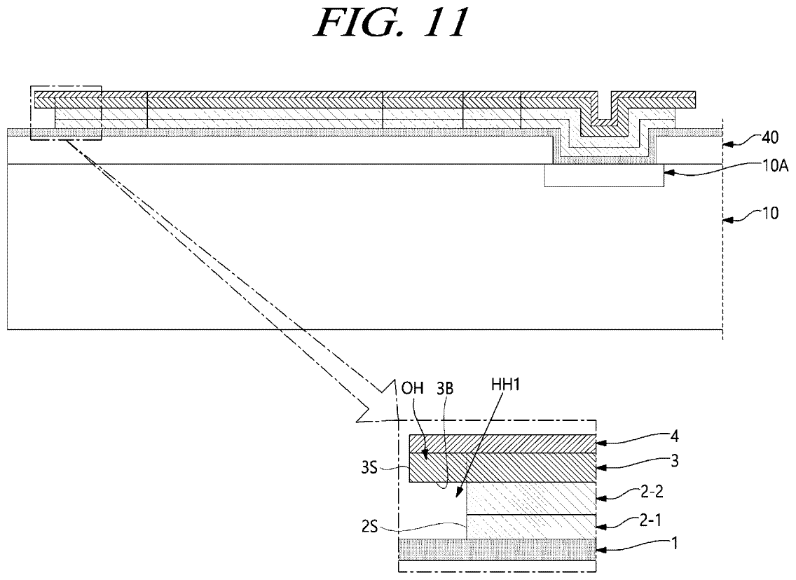

FIG. 8 to FIG. 13 are views illustrating a semiconductor device formed utilizing a method of forming a semiconductor device according to an embodiment of the present application.

Referring to FIG. 8, a pre-base metal layer 1′ may be formed on a semiconductor chip 10, and a seed layer 2-1 may be formed on the pre-base metal layer 1′.

A second dielectric layer 40 having an opening that exposes a chip pad 10A may be further disposed on the semiconductor chip 10. The pre-base metal layer 1′ may be formed on the surface of the second dielectric layer 40 and the surface of the chip pad 10A exposed by the opening of the second dielectric layer 40. The seed layer 2-1 may be formed on the surface of the pre-base metal layer 1′.

The pre-base metal layer 1′ and the seed layer 2-1 may be formed by a deposition method such as sputtering. The pre-base metal layer 1′ may include titanium or titanium tungsten, and the seed layer 2-1 may include copper.

Referring to FIG. 9, a plating resist pattern PR may be formed on the seed layer 2-1. The plating resist pattern PR may be patterned to have an opening region OR that provides a template for the redistribution line 20 of FIG. 2. The plating resist pattern PR may be patterned by forming a resist layer and selectively exposing and developing the resist layer.

In the opening region OR of the plating resist pattern PR, a conductive layer 2-2, a barrier metal layer 3, and a bonding metal layer 4 may be sequentially grown.

The conductive layer 2-2 may be grown on the seed layer 2-1 through a plating process. The barrier metal layer 3 may be grown on the conductive layer 2-2 through a plating process. The bonding metal layer 4 may be grown on the barrier metal layer 3 through a plating process. The conductive layer 2-2 may include copper, the barrier metal layer 3 may include nickel, and the bonding metal layer 4 may include gold.

Referring to FIG. 10, the plating resist pattern PR (see FIG. 9) may be removed through a strip process. In the strip process, a stripper including a sulfur(S) constituent may be used.

A section of the seed layer 2-1 that does not overlap the conductive layer 2-2 may be removed. In other words, a section of the seed layer 2-1 (see FIG. 9) exposed due to the removal of the plating resist pattern PR (see FIG. 9) may be selectively etched and removed.

Referring to FIG. 11, the side surface of the seed layer 2-1 and the side surface of the conductive layer 2-2 may be recessed through an etching process. The seed layer 2-1 and the conductive layer 2-2 that remain after the etching process may configure an electrically conductive layer 2.

An isotropic etching process may be used as the etching process. As a result of the etching process, a first horizontal groove HH1 may be formed under a flange section OH of the barrier metal layer 3. The first horizontal groove HH1 extends continuously along a side surface 2S of the electrically conductive layer 2.

As the first horizontal groove HH1 is formed, the flange section OH of the barrier metal layer 3 may have an overhang structure that is not supported by the electrically conductive layer 2. A side surface 3S of the barrier metal layer 3 may be spaced apart from the side surface 2S of the electrically conductive layer 2, and the edge section of a bottom surface 3B of the barrier metal layer 3 may be exposed between the side surface 3S of the barrier metal layer 3 and the side surface 2S of the electrically conductive layer 2.

Referring to FIG. 12, through an etching process, a section of the pre-base metal layer 1′ (see FIG. 11) that does not overlap the electrically conductive layer 2 may be removed.

In the process of etching the pre-base metal layer 1′ (see FIG. 11) such that the pre-base metal layer 1′ (see FIG. 11) does not remain in a region not overlapping the electrically conductive layer 2, over-etching may be performed. As a result of the over-etching, a second horizontal groove HH2 may be formed under the outer peripheral section of the electrically conductive layer 2. Although not illustrated, the second horizontal groove HH2 may extend continuously along a side surface 1S of a base metal layer 1.

As the second horizontal groove HH2 is formed, the outer peripheral section of the electrically conductive layer 2 has an overhang structure that is not supported by the base metal layer 1. The side surface 2S of the electrically conductive layer 2 may be spaced apart from the side surface 1S of the base metal layer 1, and the edge section of a bottom surface 2B of the electrically conductive layer 2 may be exposed between the side surface 2S of the electrically conductive layer 2 and the side surface 1S of the base metal layer 1.

The base metal layer 1, the electrically conductive layer 2, the barrier metal layer 3 and the bonding metal layer 4 may configure a redistribution line 20. The redistribution line 20 may include a wire bonding pad section 21, a bump bonding pad section 22, an overlapping pad section 23, and trace sections 24.

Referring to FIG. 13, a first dielectric layer 30 that covers the redistribution line 20 and the second dielectric layer 40 may be formed, and a first opening OP1 that exposes the wire bonding pad section 21 of the redistribution line 20 and a second opening OP2 that exposes the bump bonding pad section 22 of the redistribution line 20 may be formed in the first dielectric layer 30.

The first dielectric layer 30 may be formed to cover the overlapping pad section 23 and the trace sections 24 of the redistribution line 20. The first dielectric layer 30 may extend to cover the side surface of the wire bonding pad section 21 and cover the edge section of the top surface of the wire bonding pad section 21. The first dielectric layer 30 may be formed to cover, in the wire bonding pad section 21, a side surface 4S of the bonding metal layer 4, the side surface 3S of the barrier metal layer 3, the side surface 2S of the electrically conductive layer 2 and the side surface 1S of the base metal layer 1. The first dielectric layer 30 may extend to cover, in the wire bonding pad section 21, the edge section of the top surface 4T of the bonding metal layer 4. Accordingly, an edge EG of the first opening OP1 may be spaced apart from the side surface 4S of the bonding metal layer 4 of the wire bonding pad section 21. The first opening OP1 might not overlap the flange section OH of the barrier metal layer 3 that has the overhang structure.

The first dielectric layer 30 may be formed to fill the first horizontal groove HH1 (see FIG. 12) and cover the bottom surface 3B of the flange section OH of the barrier metal layer 3 of the wire bonding pad section 21 that protrudes beyond the side surface 2S of the electrically conductive layer 2 of the wire bonding pad section 21. The first dielectric layer 30 may fill the second horizontal groove HH2 (see FIG. 12). In the wire bonding pad section 21, the outer peripheral section of the bottom surface 2B of the electrically conductive layer 2 may protrude beyond the side surface 1S of the base metal layer 1. In the wire bonding pad section 21, the first dielectric layer 30 may be formed to cover the outer peripheral section of the bottom surface 2B of the electrically conductive layer 2.

The second opening OP2 of the first dielectric layer 30 may be formed to expose the top surface and the side surface of the bump bonding pad section 22 (see FIG. 7).

In the bump bonding pad section 22 (see FIG. 7), the second opening OP2 may be formed to expose the top surface 4T (see FIG. 7) and the side surface 4S (see FIG. 7) of the bonding metal layer 4 (see FIG. 7), the side surface 3S (see FIG. 7) of the barrier metal layer 3 (see FIG. 7), the side surface 2S (see FIG. 7) of the electrically conductive layer 2 (see FIG. 7), the edge section of the bottom surface 3B (see FIG. 7) of the barrier metal layer 3 (see FIG. 7) and the side surface 1S (see FIG. 7) of the base metal layer 1 (see FIG. 7).

The first dielectric layer 30 may be made of a photosensitive polymer material such as polyimide, and after forming the first and second openings OP1 and OP2 in the first dielectric layer 30, a baking process that bakes the photosensitive polymer material may be performed.

In a state in which the first dielectric layer 30 covers the side surface 3S of the barrier metal layer 3 of the wire bonding pad section 21 such that the side surface 3S of the barrier metal layer 3 of the wire bonding pad section 21 is not exposed to the outside, the baking process that bakes the first dielectric layer 30 may be performed.

Accordingly, in an embodiment, it is possible to prevent or mitigate a layer serving as a metal diffusion path from being generated on the side surface 3S of the barrier metal layer 3 of the wire bonding pad section 21 during the baking process. In an embodiment, when the side surface 3S of the barrier metal layer 3 is exposed, process byproducts may combine with the exposed side surface 3S to form a metal inorganic compound. In an embodiment, when the barrier metal layer 3 includes nickel, the metal inorganic compound may be nickel sulfide in which nickel combines with sulfur. In an embodiment, because the baking process is performed in the state in which the first dielectric layer 30 covers the side surface 3S of the barrier metal layer 3 of the wire bonding pad section 21, even when the baking process is performed at a temperature range in which a sulfur constituent remaining after being used in a semiconductor device manufacturing process may react with nickel, it is possible to suppress or prevent nickel sulfide from being generated on the side surface 3S of the barrier metal layer 3 of the wire bonding pad section 21. Therefore, in an embodiment, it is possible to suppress the metal of the electrically conductive layer 2 from diffusing to the bonding metal layer 4 of the wire bonding pad section 21 through nickel sulfide.

The semiconductor device 100 according to an embodiment of the present application may be manufactured into a semiconductor package.

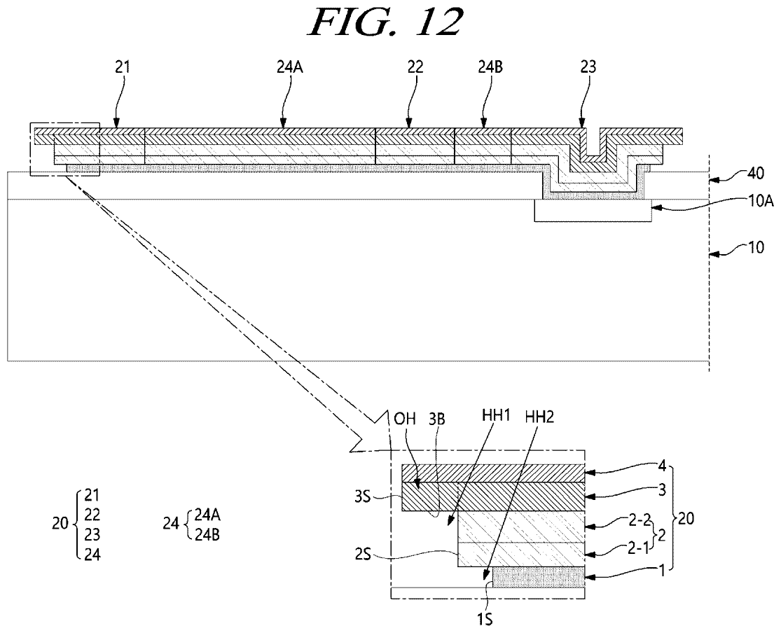

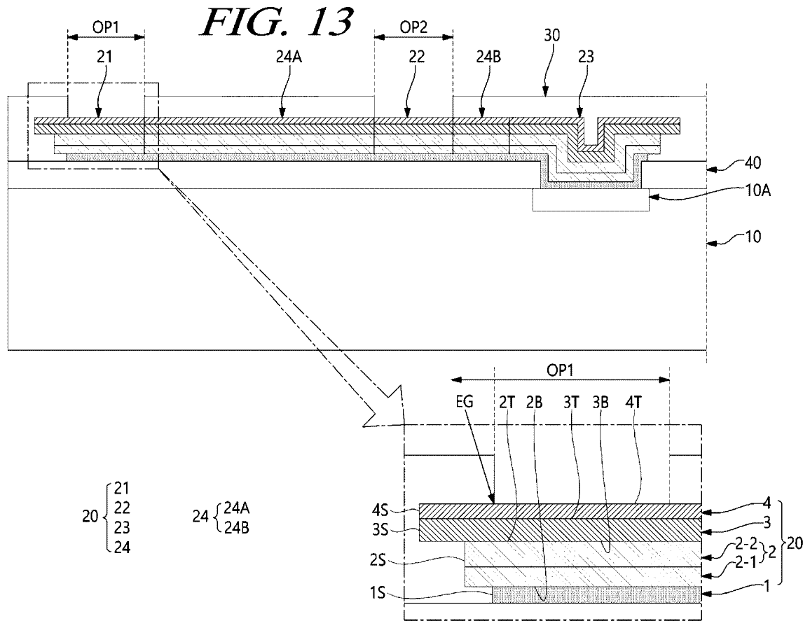

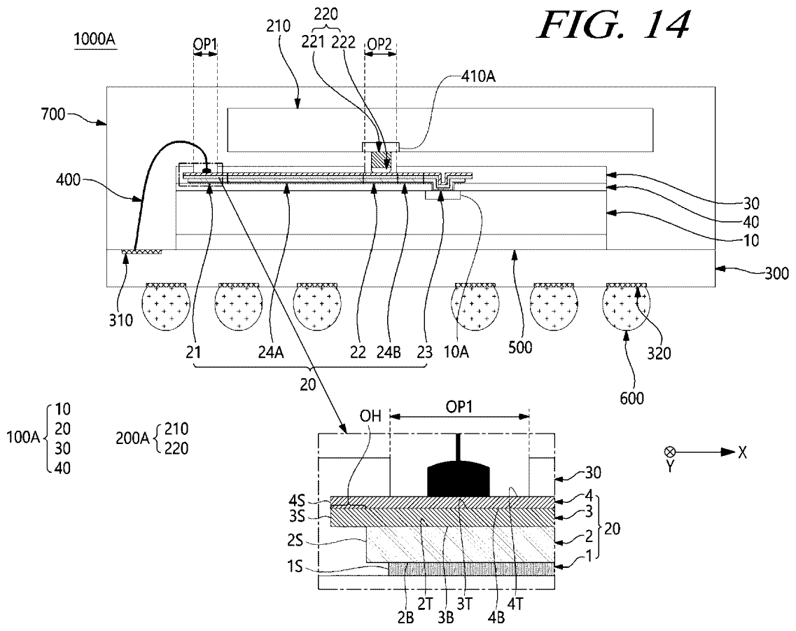

FIG. 14 is a cross-sectional view of a semiconductor package according to an embodiment of the present application.

Referring to FIG. 14, the semiconductor package according to an embodiment of the present application may include a first semiconductor device 100A, a second semiconductor device 200A, a package substrate 300, and a metal wire 400. The semiconductor package according to an embodiment of the present application may further include an adhesive layer 500, a connection structure 600, and a molding member 700.

The package substrate 300 may include a circuit and/or interconnection structure that electrically connects the first semiconductor device 100A and the second semiconductor device 200A to an external device. For example, the package substrate 300 may include a printed circuit board (PCB), an interposer, a redistribution layer, or the like. A top surface substrate pad 310 may be disposed on the top surface of the package substrate 300. Top surface substrate pads 310 may include bond fingers. Bottom surface substrate pads 320 that connect to connection structures 600 may be disposed on the bottom surface of the package substrate 300. The connection structures 600 may be electrically connected to another semiconductor package or printed circuit board. The connection structures 600 may include solder balls. When the connection structure 600 is a solder ball, the bottom surface substrate pad 320 may include a ball land. Although not illustrated, the top surface substrate pad 310 may be electrically connected to a corresponding bottom surface substrate pad 320 through the circuit and/or interconnection structure in the package substrate 300.

The first semiconductor device 100A may be the semiconductor device 100 described with reference to FIG. 1 to FIG. 13. The first semiconductor device 100A may include a first semiconductor chip 10, redistribution lines 20, and a first dielectric layer 30. The first semiconductor device 100A may further include a second dielectric layer 40 that covers the first semiconductor chip 10 under the redistribution lines 20 and has an opening that exposes a chip pad 10A of the first semiconductor chip 10.

The first semiconductor chip 10 may be disposed on the package substrate 300 in a face-up type such that an active surface on which the chip pad 10A is disposed faces up, and the inactive surface of the first semiconductor chip 10 may be attached onto the package substrate 300 by the adhesive layer 500.

The redistribution line 20 is disposed on the second dielectric layer 40 and the chip pad 10A of the first semiconductor chip 10, and extends to the edge of the first semiconductor chip 10 while being connected to the chip pad 10A of the first semiconductor chip 10. Although only one chip pad 10A and only one redistribution line 20 are illustrated in the cross-section shown in FIG. 14, a plurality of chip pads 10A are disposed in at least one column in the Y-axis direction of an X-Y plane, and a plurality of redistribution lines 20 are connected to the plurality of chip pads 10A, respectively.

The redistribution line 20 may include a wire bonding pad section 21 disposed adjacent to the edge of the first semiconductor chip 10, a bump bonding pad section 22 connected to the bump of a second semiconductor chip 210, an overlapping pad section 23 connected to the chip pads 10A of the first semiconductor chip 10, and trace sections 24 that connected together.

The bump bonding pad section 22 of the redistribution line 20 may be disposed by being offset in the X-axis direction with respect to the chip pad 10A of the first semiconductor chip 10.

The redistribution line 20 may include an electrically conductive layer 2, a barrier metal layer 3 on the electrically conductive layer 2, and a bonding metal layer 4 on the barrier metal layer 3. The redistribution line 20 may further include a base metal layer 1 under the electrically conductive layer 2.

The base metal layer 1 may be disposed on the surface of the second dielectric layer 40 and the surface of the chip pad 10A. The base metal layer 1 may contact the chip pad 10A of the first semiconductor chip 10, and may electrically connect the chip pad 10A and the electrically conductive layer 2.

The electrically conductive layer 2 may be disposed on the base metal layer 1. The outer peripheral section of the electrically conductive layer 2 has an overhang structure that is not supported by the underlying base metal layer 1. The outer peripheral section of the electrically conductive layer 2 has the overhang structure that is continuous along a side surface 1S of the base metal layer 1.

The barrier metal layer 3 is disposed on a top surface 2T of the electrically conductive layer 2. The barrier metal layer 3 has a flange section OH that protrudes beyond a side surface 2S of the electrically conductive layer 2. The flange section OH of the barrier metal layer 3 has an overhang structure that is not supported by the underlying electrically conductive layer 2. The flange section OH of the barrier metal layer 3 has the overhang structure that is continuous along the side surface 2S of the electrically conductive layer 2. A side surface 3S of the barrier metal layer 3 may protrude beyond the side surface 2S of the electrically conductive layer 2.

The bonding metal layer 4 is disposed on a top surface 3T of the barrier metal layer 3.

The first dielectric layer 30 is disposed on the first semiconductor chip 10 and the redistribution line 20, and has a first opening OP1 that exposes the wire bonding pad section 21 of the redistribution line 20 and a second opening OP2 that exposes the bump bonding pad section 22 of the redistribution line 20. The first dielectric layer 30 may extend to cover the side surface of the wire bonding pad section 21 and cover the edge section of the top surface the wire bonding pad section 21.

The first dielectric layer 30 is provided to cover the side surface of the wire bonding pad section 21. The first dielectric layer 30 is provided to cover, in the wire bonding pad section 21, a side surface 4S of the bonding metal layer 4, the side surface 3S of the barrier metal layer 3, the side surface 2S of the electrically conductive layer 2 and the side surface 1S of the base metal layer 1. In addition, the first dielectric layer 30 is provided to cover, in the wire bonding pad section 21, the edge section of a bottom surface 3B of the barrier metal layer 3 between the side surface 2S of the electrically conductive layer 2 and the side surface 3S of the barrier metal layer 3.

In an embodiment, in the wire bonding pad section 21, the first dielectric layer 30 may cover the side surface 3S of the barrier metal layer 3 to prevent or mitigate a layer acting as a metal diffusion path from being generated. In an embodiment, because the first dielectric layer 30 suppresses the generation of the metal diffusion path, it is possible to suppress or prevent the occurrence of a defect in which the surface of the bonding metal layer 4 is discolored or the metal wire 400 comes off without being bonded to the bonding metal layer 4.

The first dielectric layer 30 may extend to cover, in the wire bonding pad section 21, the edge section of a top surface 4T of the bonding metal layer 4. Accordingly, an edge EG of the first opening OP1 may be spaced apart from the side surface 4S of the bonding metal layer 4. The edge EG of the first opening OP1 may be disposed on the top surface 4T of the bonding metal layer 4, and the first dielectric layer 30 may continuously cover the edge section of the top surface 4T of the bonding metal layer 4 along the edge EG of the first opening OP1.

The metal wire 400 may be bonded to the exposed section of the top surface 4T of the bonding metal layer 4 of the wire bonding pad section 21 exposed by the first opening OP1 of the first dielectric layer 30. The exposed section of the top surface 4T of the bonding metal layer 4 of the wire bonding pad section 21 exposed by the first opening OP1 may be a wire bonding area. The wire bonding area might not overlap the flange section OH of the barrier metal layer 3 that has the overhang structure.

The second semiconductor device 200A includes the second semiconductor chip 210 and conductive bumps 220 connected to chip pads 410A of the second semiconductor chip 210. The second semiconductor chip 210 is connected to the bump bonding pad section 22 of the redistribution line 20 of the first semiconductor device 100A through the conductive bump 220. Although only one chip pad 410A and only one conductive bump 220 are illustrated in the cross-section shown in FIG. 14, a plurality of chip pads 410A may be disposed in at least one column in the Y-axis direction of the X-Y plane, and a plurality of conductive bumps 220 may be connected to the plurality of chip pads 410A, respectively.

The second semiconductor chip 210 may be substantially the same semiconductor chip as the first semiconductor chip 10. In this case, the chip pads 410A of the second semiconductor chip 210 may have the same arrangement structure as the chip pads 10A of the first semiconductor chip 10.

Apart from the first semiconductor chip 10 disposed such that the active surface on which the chip pads 10A are disposed faces up, the second semiconductor chip 210 may be disposed over the first semiconductor device 100A in a face-down type such that an active surface on which the chip pads 410A are disposed faces down.

The conductive bumps 220 may be positioned to overlap the chip pads 410A. The conductive bump 220 may include a conductive pillar 221 and a solder layer 222. The conductive pillar 221 may be disposed under the second semiconductor chip 210. The solder layer 222 may be disposed at the lower end of the conductive pillar 221, and may be bonded to the bump bonding pad section 22 of the redistribution line 20.

The second semiconductor chip 210 may be connected to the first semiconductor device 100A while being offset in the X-axis direction with respect to the first semiconductor chip 10. In an embodiment, because the bump bonding pad sections 22 of the redistribution lines 20 of the first semiconductor device 100A are disposed by being offset in the X-axis direction with respect to the chip pads 10A of the first semiconductor chip 10, the arrangement of the chip pads 410A of the second semiconductor chip 210 is the same as the arrangement of the chip pads 10A of the first semiconductor chip 10 and the conductive bumps 220 overlap the chip pads 410A of the second semiconductor chip 210, the second semiconductor chip 210 may be connected to the first semiconductor device 100A in a state in which it is offset in the X-axis direction with respect to the first semiconductor chip 10. Accordingly, the first semiconductor chip 10 and the second semiconductor chip 210 may partially overlap each other.

The molding member 700 is formed to surround the first and second semiconductor devices 100A and 200A and the metal wires 400. The molding member 700 may seal the first and second semiconductor devices 100A and 200A and the metal wires 400 to protect the first and second semiconductor devices 100A and 200A and the metal wires 400 from an external environment. The first semiconductor device 100A and the second semiconductor device 200B may be spaced apart from each other, and the molding member 700 may extend between the first semiconductor device 100A and the second semiconductor device 200B. In FIG. 14, the molding member 700 is formed to substantially completely cover the second semiconductor device 200A. The present application is not limited to this example, and the molding member 700 may be formed to expose a section of the surface of the second semiconductor device 200A.

In an embodiment, the molding member 700 may include an encapsulant material such as an epoxy molding compound (EMC) material. In an embodiment, the encapsulant material may include, for example, an epoxy resin constituent and fillers dispersed therein.

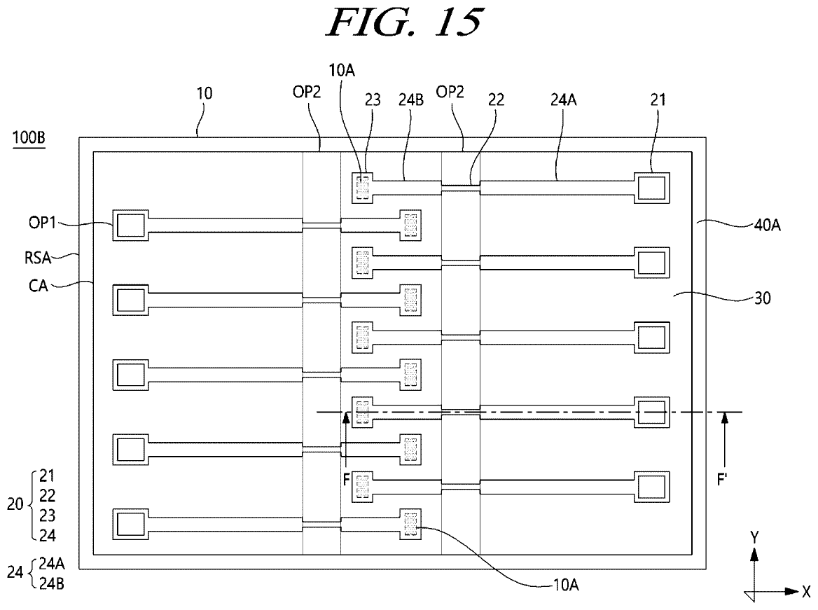

FIG. 15 is a plan view of a semiconductor device according to an embodiment of the present application, and FIG. 16 is a cross-sectional view taken along a line F-F′ of FIG. 15.

Referring to FIG. 15 and FIG. 16, a semiconductor device 100B includes a semiconductor chip 10, a plurality of redistribution lines 20, a first dielectric layer 40A, and a second dielectric layer 30.

The semiconductor device 100B has a chip region CA and a residual scribe lane RSA. The semiconductor device 100B is obtained by dicing along a scribe lane after fabrication on a wafer. The residual scribe lane RSA is the section of the scribe lane that is not removed during the dicing process and surrounds the periphery of the chip region CA.

The semiconductor chip 10 may include nonvolatile memory such as NAND, NOR, PRAM, and MRAM, volatile memory such as DRAM and SRAM, and a processor such as a CPU, a GPU, an AP, and/or an NPU.

The semiconductor chip 10 includes a chip body 11, a chip pad 10A, and a passivation layer 12.

The chip pad 10A is disposed on the chip body 11. The chip pad 10A is electrically connected to an integrated circuit within the semiconductor chip 10 through an interconnection pattern (not illustrated) inside the chip body 11.

The passivation layer 12 is disposed on the chip region CA of the chip body 11. The passivation layer 12 covers the upper surface of the chip region CA of the chip body 11. A third opening OP3 is formed in the passivation layer 12 through which the chip pad 10A is exposed. The perimeter of the passivation layer 12 constitutes a boundary between the chip region CA and the residual scribe lane RSA. The chip region CA that includes the passivation layer 12 and the residual scribe lane RSA of the semiconductor chip 10 are formed at different heights or levels.

The passivation layer 12 may include various insulating materials. For example, the passivation layer 12 may include photosensitive polyimide such as polyimide isoindro quindzoline (PIQ).

The first dielectric layer 40A is disposed on the passivation layer 12 and the residual scribe lane RSA of the chip body 11 and includes an opening through which the chip pad 10A is exposed. The first dielectric layer 40A may cover the passivation layer 12 and the residual scribe lane RSA of the chip body 11.

The first dielectric layer 40A covers the residual scribe lane RSA of the chip body 11. The first dielectric layer 40A may prevent a metal wire bonded to a wire bonding pad section 21 of the redistribution line 20 from contacting the semiconductor chip 10.

When the first dielectric layer 40A covers both the passivation layer 12 and the residual scribe lane RSA of the chip body 11 of the semiconductor chip 10, the first dielectric layer 40A compensates for the height difference between the surface of the chip body 11 and the residual scribe lane RSA of the semiconductor chip 10 due to the thickness of the passivation layer 12. The first dielectric layer 40A may be formed as a single unbroken layer or a combination of multiple sections that may contact each other.

The first dielectric layer 40A includes a first section 41 disposed on the passivation layer 12 and a second section 42 disposed on the residual scribe lane RSA of the chip body 11. The second section 42 is thicker than the first section 41. The height or level difference between the chip region CA and the residual scribe lane RSA is compensated for because the second section 42 of the first dielectric layer 40A is thicker than the first section 41 of the first dielectric layer 40A.

The first dielectric layer 40A may include various insulating materials. The first dielectric layer 40A may be made of a polymer-based insulating layer. The polymer-based insulating layer fills a region that has a lower height or level in the semiconductor chip 10, such as the residual scribe lane RSA, to compensate for the different heights between the structures of the chip region CA and the residual scribe lane RSA. In an embodiment, the first dielectric layer 40A may include photosensitive polymer such as polyimide.

The redistribution line 20 is disposed on the first dielectric layer 40A and the chip pad 10A exposed through an opening in the first dielectric layer 40A.

The redistribution line 20 includes the wire bonding pad section 21, a bump bonding pad section 22, an overlapping pad section 23, and trace sections 24 connected together. The trace sections 24 include a first trace section 24A and a second trace section 24B. The first trace section 24A connects the wire bonding pad section 21 and the bump bonding pad section 22, and the second trace section 24B connects the bump bonding pad section 22 and the overlapping pad section 23.

The wire bonding pad sections 21 of the redistribution lines 20 are disposed near an edge of the chip region CA adjacent to the residual scribe lane RSA. For example, the wire bonding pad sections 21 of the redistribution lines 20 are disposed near in both edges of the chip region CA in the X direction. The wire bonding pad sections 21 are disposed on the first section 41 of the first dielectric layer 40A. The wire bonding pad sections 21 overlap, or are disposed over, the passivation layer 12 of the semiconductor chip 10.

The overlapping pad sections 23 of the redistribution lines 20 are disposed in a center region of the semiconductor chip 10. For example, the overlapping pad sections 23 of the redistribution lines 20 are disposed in a center region of the chip region CA in the X direction.

The overlapping pad section 23 is disposed over the chip pad 10A as shown in FIG. 16. The overlapping pad section 23 contacts the chip pad 10A. The overlapping pad section 23 is connected to the second trace section 24B and is connected to the wire bonding pad section 21 through the bump bonding pad section 22 and the first trace section 24A. The redistribution line 20 extends between the center region of the chip region CA, where the chip pad 10A is disposed, and an area near an edge of the chip region CA, where the wire bonding pad section 21 is disposed.

The redistribution line 20 includes a base metal layer 1, an electrically conductive layer 2 on the base metal layer 1, a barrier metal layer 3 on the electrically conductive layer 2, and a bonding metal layer 4 on the barrier metal layer 3. The base metal layer 1 is optional.

The electrically conductive layer 2 is disposed on the base metal layer 1. The outer peripheral section of the electrically conductive layer 2 includes an overhang structure not supported by the underlying base metal layer 1. The overhang structure of the outer peripheral section of the electrically conductive layer 2 is continuous along the side surface of the base metal layer 1.

The barrier metal layer 3 includes a flange section OH that protrudes beyond a vertical side surface of the electrically conductive layer 2. The flange section OH of the barrier metal layer 3 is an overhang structure not supported by the underlying electrically conductive layer 2. The flange section OH of the barrier metal layer 3 has the continuous overhang structure that is continuous along the side surface of the electrically conductive layer 2. The side surface of the barrier metal layer 3 protrudes beyond the side surface of the electrically conductive layer 2.

The second dielectric layer 30 is disposed on the first dielectric layer 40A and the redistribution lines 20. A first opening OP1 is formed in the second dielectric layer 30 through which the wire bonding pad section 21 is exposed, and a second opening OP2 is formed in the second dielectric layer 30 through which the bump bonding pad section 22 is exposed.

The second dielectric layer 30 covers the overlapping pad sections 23 and the trace sections 24 of the redistribution lines 20. The second dielectric layer 30 extends along an upper surface of the bonding metal layer 4 between the first opening OP1 that exposes the wire bonding pad section 21 and the second opening OP2 that exposes the bump bonding pad section 22. The second dielectric layer 30 is provided to cover, in the wire bonding pad section 21, the side surfaces of the bonding metal layer 4, the side surfaces of the barrier metal layer 3, the side surfaces of the electrically conductive layer 2, and the side surfaces of the base metal layer 1.

The second dielectric layer 30 is disposed on the chip region CA. The second dielectric layer 30 is not disposed on the residual scribe lane RSA. The second dielectric layer 30 covers the first section 41 of the first dielectric layer 40A, and does not cover the second section 42 of the first dielectric layer 40A. Because the second section 42 of the first dielectric layer 40A protrudes beyond the outer periphery of the second dielectric layer 30, a step structure is formed. The second dielectric layer 30 may include photosensitive polymer such as polyimide.

A plurality of first openings OP1 individually expose the wire bonding pad sections 21 of the redistribution lines 20. The first openings OP1 correspond on a one-to-one basis to the wire bonding pad sections 21 and expose corresponding wire bonding pad sections 21. The first opening OP1 is spaced apart by distance d4 from the second section 42 of the first dielectric layer 40A.

A metal wire (not shown) is bonded to the surface of the wire bonding pad section 21 exposed through the first opening OP1 of the second dielectric layer 30.

The surface of the bonding metal layer 4 of the wire bonding pad section 21 exposed through the first opening OP1 is referred to as a wire bonding area. The first opening OP1 is horizontally spaced apart from the flange section OH of the barrier metal layer 3. The first opening OP1 does not overlap, or is not located directly over, the flange section OH of the barrier metal layer 3 in a vertical or Z direction in this example. The wire bonding area is spaced apart from the flange section OH of the barrier metal layer 3.

As illustrated in FIG. 15, second openings OP2 are configured along a line that extends in the Y direction to simultaneously expose the bump bonding pad sections 22 distributed in the Y direction. Two second openings OP2 are formed in two lines extending in the Y direction in the second dielectric layer 30 to correspond to the two lines of bump bonding pad sections 22 disposed in the Y direction. A conductive bump is advantageously bonded to the surface of the bump bonding pad section 22 exposed through the second opening OP2 of the second dielectric layer 30.

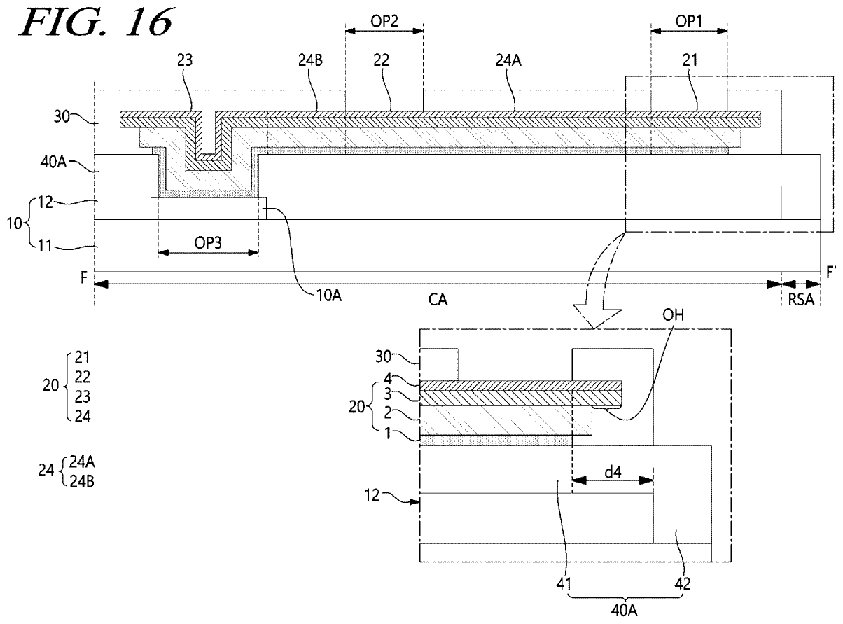

FIG. 17 to FIG. 21 are views illustrating a semiconductor device formed utilizing a method of forming the semiconductor device according to an embodiment of the present application.

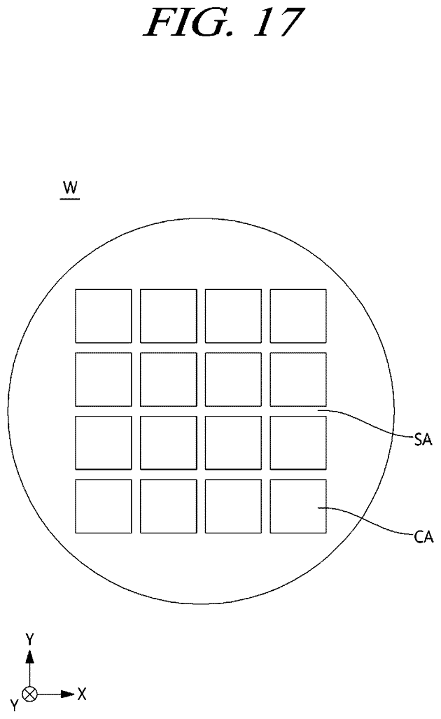

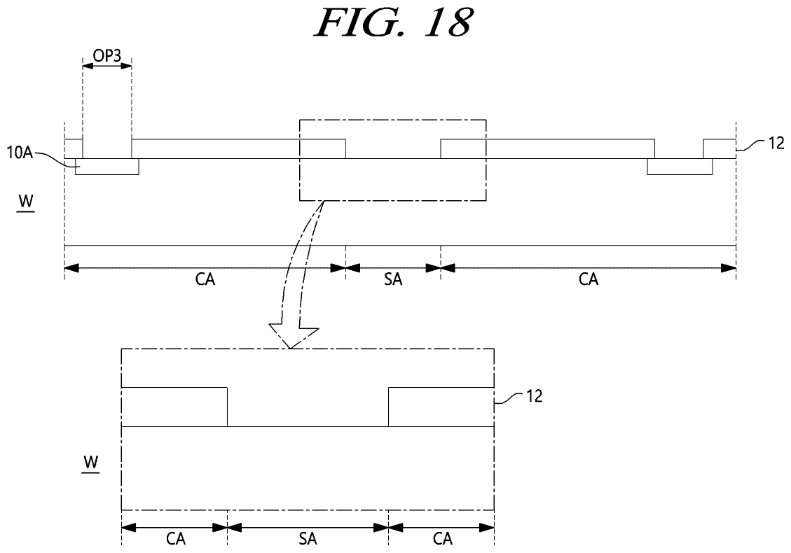

FIG. 17 is a plan view of a wafer W fabricated according to an embodiment of the present application, and FIG. 18 to FIG. 21 are cross-sectional views illustrating sections of two consecutive chip regions CA with a scribe lane SA interposed between consecutive chip regions CA.

Referring to FIG. 17, the wafer W includes a plurality of chip regions CA and the scribe lane SA. The chip regions CA have a square shape when viewed in a plan view. The chip regions CA are disposed in a matrix form in the X direction and Y direction and are spaced apart from each other.

The scribe lane SA surrounds each of the chip regions CA. The scribe lane SA includes a dicing region utilized during dicing to separate the wafer W into a plurality of semiconductor chips.

Referring to FIG. 18, each of the chip regions CA of the wafer W includes an integrated circuit (not illustrated) and a chip pad 10A. A passivation layer 12 is disposed on the chip region CA. A third opening OP3 is formed in the passivation layer 12 to expose the chip pad 10A. The passivation layer 12 covers the chip region CA except for the third opening OP3 through which the chip pad 10A is exposed. The perimeter of the passivation layer 12 constitutes the boundary between the chip region CA and the scribe lane SA. The chip region CA that includes the passivation layer 12 and the scribe lane SA of the wafer W are formed at different heights or levels.

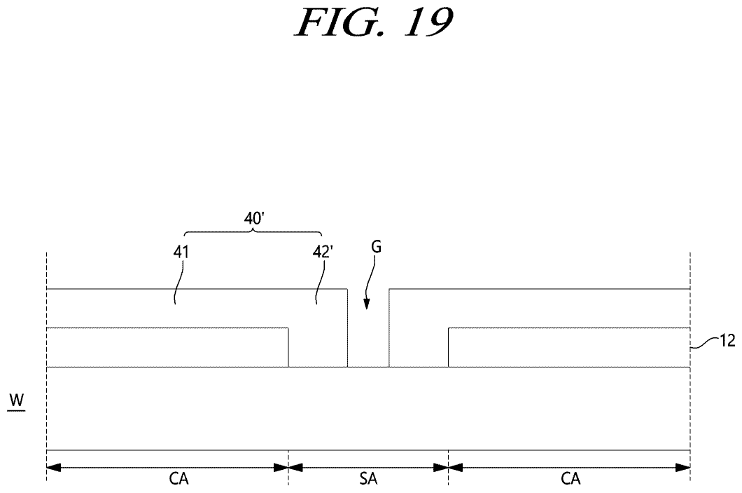

Referring to FIG. 19, a pre-first dielectric layer 40A′, including an opening that exposes the chip pad 10A such as shown in FIG. 18, is formed on the wafer W. The pre-first dielectric layer 40A′ is a pre-structure that forms the first dielectric layer 40A of FIG. 16.

The pre-first dielectric layer 40A′ covers the passivation layer 12 and the scribe lane SA of the wafer W.

When the pre-first dielectric layer 40A′ covers both the passivation layer 12 and the scribe lane SA of the wafer W, the pre-first dielectric layer 40A′ compensates for the height difference between the surfaces of the chip region CA and the scribe lane SA of the wafer W due to the thickness of the passivation layer 12.

The pre-first dielectric layer 40A′ includes a first section 41 disposed on the passivation layer 12 and a second section 42′ disposed on the scribe lane SA. The second section 42′ is thicker than the first section 41. The height or level difference between the chip region CA and the scribe lane SA is compensated for because the second section 42′ of the pre-first dielectric layer 40A′ is thicker than the first section 41 of the pre-first dielectric layer 40A′.

The pre-first dielectric layer 40A′ may include various insulating materials. The pre-first dielectric layer 40A′ may be made of a polymer-based insulating layer. The polymer-based insulating layer fills a region that has a lower height or level in the wafer W, such as the scribe lane SA, to compensate for the different heights between the structures of the chip region CA and the scribe lane SA. In an embodiment, the pre-first dielectric layer 40A′ may include photosensitive polymer such as polyimide. The pre-first dielectric layer 40A′ may be formed by applying photosensitive polymer and forming an opening to exposes the chip pad 10A in the photosensitive polymer through exposure and development processes.

A groove G is formed in the pre-first dielectric layer 40A′ in the scribe lane SA. The width of the groove G is narrower than the width of the scribe lane SA. The groove G is formed in the scribe lane SA to surround the chip region CA.

The groove G facilitates division of the wafer W in a dicing process, thereby improving the speed and efficiency of the dicing process. The groove G may also reduce stress that may occur during the dicing process.

The groove G may be formed during the process including forming the opening OP3 in the pre-first dielectric layer 40A′. In an embodiment, the groove G may not be formed.

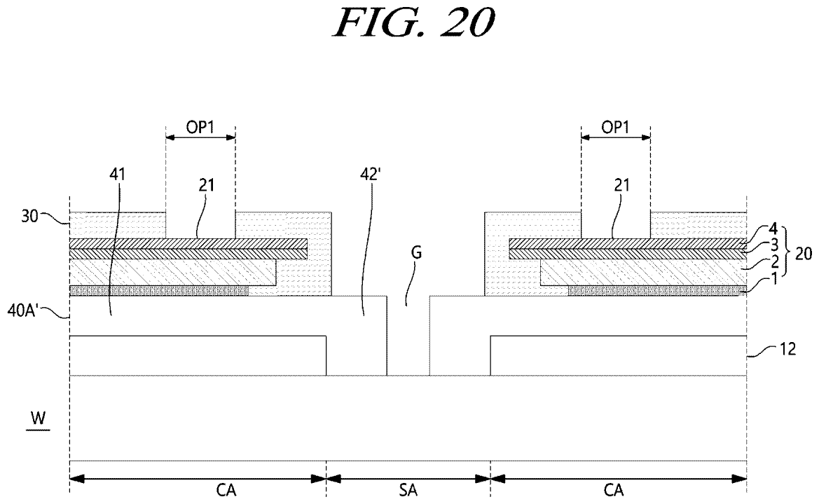

Referring to FIG. 20, a redistribution line 20 is formed on the chip pad 10A and on the chip region CA of the pre-first dielectric layer 40A′.

The redistribution line 20 is configured to include a base metal layer 1, an electrically conductive layer 2 on the base metal layer 1, a barrier metal layer 3 on the electrically conductive layer 2, and a bonding metal layer 4 on the barrier metal layer 3. The base metal layer 1 is optional.

As shown for example in FIG. 15 and FIG. 16, the redistribution line 20 includes a wire bonding pad section 21, a bump bonding pad section 22, an overlapping pad section 23, and trace sections 24 connected together. The overlapping pad section 23 is disposed in the center region of the chip region CA, and the wire bonding pad section 21 is disposed in near an edge of the chip region CA.

The wire bonding pad section 21 is disposed on the first section 41 of the pre-first dielectric layer 40A′. The wire bonding pad section 21 vertically overlaps, or is disposed vertically over, the passivation layer 12.

A second dielectric layer 30 is formed on the pre-first dielectric layer 40A′ and the redistribution lines 20.

The second dielectric layer 30 covers the pre-first dielectric layer 40A′ and the redistribution line 20 in the chip region CA. The second dielectric layer 30 has a first opening OP1 through which the wire bonding pad section 21 is exposed and a second opening OP2 through which the bump bonding pad section 22 is exposed. The first opening OP1 is horizontally spaced apart from the second section 42′ of the pre-first dielectric layer 40A′. The first opening OP1 does not vertically overlap, or is not vertically disposed over, the second section 42′ of the pre-first dielectric layer 40A′.

Openings in the second dielectric layer 30 expose the scribe lane SA. The pre-first dielectric layer 40A′ is not covered with the second dielectric layer 30 in the scribe lane SA.

The second dielectric layer 30 may include photosensitive polymer. The second dielectric layer 30 may be formed by applying photosensitive polymer and performing exposure and development processes to form the first opening OP1, through which the wire bonding pad section 21 is exposed, and the second opening OP2, through which the bump bonding pad section 22 is exposed. The photosensitive polymer is removed from the scribe lane SA.

When the distance between a chip region and a scribe lane in the Z direction is large, a wire bonding pad section located near an edge of the chip region may be sloped. For example, the wire bonding pad section may have a slope that tapers downward closer to the scribe lane. For example, a developer used during the development process to forms the first opening might not be distributed evenly, and a defect may occur as a result. When the developer is excessively supplied to the lower section of the sloped surface of the wire bonding pad section, a defect may occur because the developer penetrates the interface between the wire bonding pad section and the second dielectric layer, and the second dielectric layer is delaminated by the penetrated developer. At the upper section of the sloped surface of the wire bonding pad section, due to lack of the developer, the photosensitive polymer might not be removed and residue may be generated.

According to an embodiment of the present application, the height difference between the chip region CA and the scribe lane SA may be compensated for by disposing the pre-first dielectric layer 40A′ in the scribe lane SA. The wire bonding pad section 21 may be formed without a slope or with a gentler slope. Accordingly, delamination and residue generation due to uneven distribution of the developer used during the development process that forms the first opening OP1 in the second dielectric layer 30 may be suppressed or reduced.

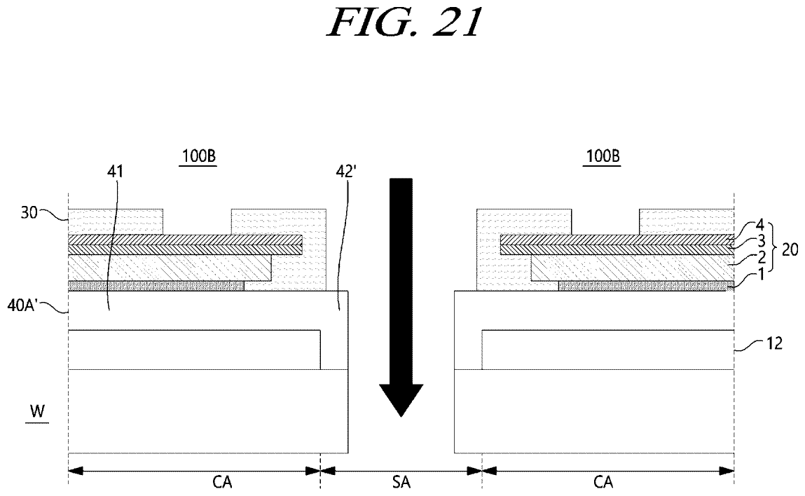

Referring to FIG. 21, by dicing the pre-first dielectric layer 40A′ and the wafer W along the scribe lane SA, semiconductor devices 100B are separated.

The width of the groove G of the pre-first dielectric layer 40′ is narrower than a width of the dicing cut by which the pre-first dielectric layer 40A′ and the wafer W are divided during the dicing process. The outermost walls of the second sections 42′ of the pre-first dielectric layers 40A′ adjacent to the groove G may be removed during the dicing process, resulting in an opening wider than the groove G.

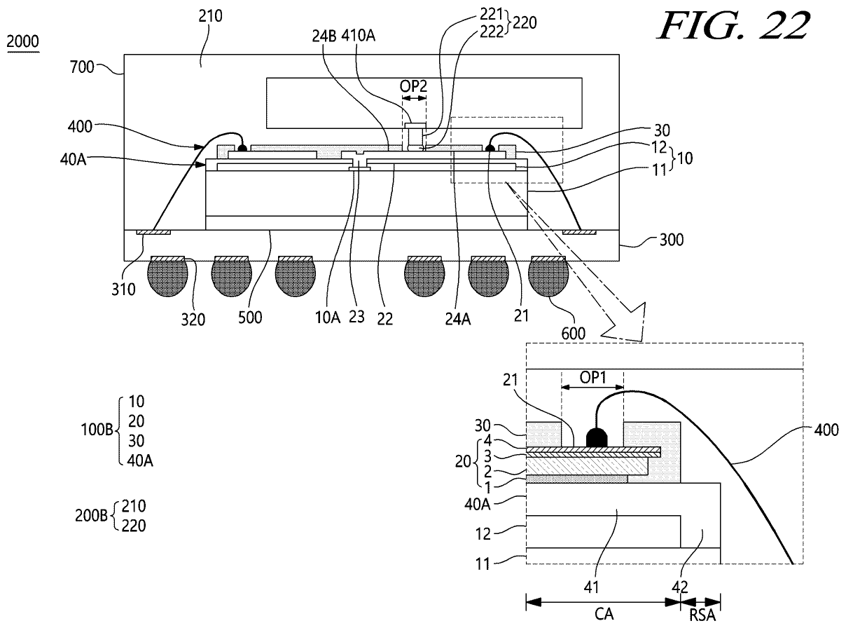

FIG. 22 is a cross-sectional view of a semiconductor package according to an embodiment of the present application.

Referring to FIG. 22, a semiconductor package 2000 according to an embodiment of the present application includes a first semiconductor device 100B, a second semiconductor device 200B, a package substrate 300, and metal wires 400. The semiconductor package 2000 according to an embodiment of the present application, further includes an adhesive layer 500, connection structures 600, and a molding member 700.

Upper substrate pads 310 are disposed along the upper surface of the package substrate 300, and lower substrate pads 320 that connect to the connection structures 600 are disposed along the lower surface of the package substrate 300. The connection structures 600 may be electrically connected to another semiconductor package or a printed circuit board. The connection structures 600 may include solder balls.

The first semiconductor device 100B may be the semiconductor device described with reference to FIG. 16 to FIG. 21. The first semiconductor device 100B includes a first semiconductor chip 10, redistribution lines 20, a first dielectric layer 40A, and a second dielectric layer 30.

The first semiconductor chip 10 includes a chip body 11, a chip pad 10A, and a passivation layer 12. The passivation layer 12 is disposed on a chip region CA of the chip body 11 and includes an opening through which the chip pad 10A is exposed. The perimeter of the passivation layer 12 constitutes the boundary between the chip region CA and a residual scribe lane RSA. The chip region CA that includes the passivation layer 12 and the residual scribe lane RSA of the first semiconductor chip 10 are formed at different heights or levels.

The first semiconductor chip 10 is disposed on the package substrate 300 such that the active surface of the first semiconductor chip 10, on which the chip pad 10A is disposed, faces upward, and the inactive surface, opposite to the active surface, of the first semiconductor chip 10 is attached to the package substrate 300 by the adhesive layer 500.

The first dielectric layer 40A is disposed on the passivation layer 12 and the residual scribe lane RSA of the chip body 11 and includes an opening through which the chip pad 10A is exposed. The first dielectric layer 40A covers the passivation layer 12 and the residual scribe lane RSA of the chip body 11.

The first dielectric layer 40A covers the residual scribe lane RSA of the chip body 11. The first dielectric layer 40A may prevent the metal wire 400 bonded to a wire bonding pad section 21 of the redistribution line 20 from contacting the first semiconductor chip 10.

The first dielectric layer 40A includes a first section 41 disposed on the passivation layer 12 and a second section 42 disposed on the residual scribe lane RSA of the chip body 11. The second section 42 is thicker than the first section 41. The height or level difference between the chip region CA and the residual scribe lane RSA is compensated for because the second section 42 of the first dielectric layer 40A is thicker than the first section 41 of the first dielectric layer 40A.

The redistribution line 20 is disposed on the first dielectric layer 40A and the chip pad 10A of the first semiconductor chip 10 and extends between an area near the edge of the first semiconductor chip 10 and the chip pad 10A of the first semiconductor chip 10.

The redistribution line 20 includes the wire bonding pad section 21 disposed near the edge of the first semiconductor chip 10, a bump bonding pad section 22 connected to a bump of the second semiconductor device 200B, an overlapping pad section 23 connected to the chip pad 10A of the first semiconductor chip 10, and trace sections 24 connected together. The trace sections 24 include a first trace section 24A that connects the wire bonding pad section 21 and the bump bonding pad section 22 and a second trace section 24B that connects the bump bonding pad section 22 and the overlapping pad section 23.

The wire bonding pad sections 21 of the redistribution lines 20 are disposed near an edge of the chip region CA adjacent to the residual scribe lane RSA. The wire bonding pad sections 21 are disposed on the first section 41 of the first dielectric layer 40A. The wire bonding pad sections 21 are horizontally spaced apart from the second section 42 of the first dielectric layer 40A in the X direction. The wire bonding pad sections 21 vertically overlap, or are disposed vertically over, the passivation layer 12 of the first semiconductor chip 10.

The bump bonding pad section 22 of the redistribution line 20 is disposed offset in the X direction with respect to the chip pad 10A of the first semiconductor chip 10.

The redistribution line 20 includes a base metal layer 1, an electrically conductive layer 2 on the base metal layer 1, a barrier metal layer 3 on the electrically conductive layer 2, and a bonding metal layer 4 on the barrier metal layer 3. The base metal layer 1 is optional.

The base metal layer 1 is disposed on the surface of the first dielectric layer 40A and the surface of the chip pad 10A. The base metal layer 1 contacts the chip pad 10A of the first semiconductor chip 10 and electrically connects the chip pad 10A and the electrically conductive layer 2.

The second dielectric layer 30 is disposed on the first semiconductor chip 10 and the redistribution line 20. A first opening OP1 is formed in the second dielectric layer 30 through which the wire bonding pad section 21 of the redistribution line 20 is exposed, and a second opening OP2 is formed in the second dielectric layer 30 through which the bump bonding pad section 22 of the redistribution line 20 is disposed. The second dielectric layer 30 covers the side surfaces of the wire bonding pad section 21 and extends to cover a part of the upper surface of the wire bonding pad section 21. The second dielectric layer 30 extends along the upper surface of the bonding metal layer 4 such that the second dielectric layer 30 is adjacent to the openings OP1 and OP2 through which the wire bonding pad section 21 and the bump bonding pad section 22 are exposed, respectively.

The second dielectric layer 30 is disposed on the chip region CA. The second dielectric layer 30 is not disposed on the residual scribe lane RSA. The second dielectric layer 30 covers the first section 41 of the first dielectric layer 40A and does not cover the second section 42 of the first dielectric layer 40A. Because the second section 42 of the second section 42 of the first dielectric layer 40A protrudes beyond the outer periphery of the second dielectric layer 30, a step structure is formed.

The metal wire 400 is bonded to the exposed surface of the bonding metal layer 4 of the wire bonding pad section 21 exposed through the first opening OP1 of the second dielectric layer 30. The first opening OP1 is horizontally spaced apart from the second section 42 of the first dielectric layer 40A. The surface of the bonding metal layer 4 of the wire bonding pad section 21 exposed through the first opening OP1 is referred to as a wire bonding area.

The second semiconductor device 200B includes a second semiconductor chip 210 and conductive bumps 220 connected to chip pads 410A of the second semiconductor chip 210. The second semiconductor chip 210 is connected to the bump bonding pad section 22 of the redistribution line 20 of the first semiconductor device 100B through the conductive bump 220.

The second semiconductor chip 210 may be a semiconductor chip that is substantially similar to the first semiconductor chip 10. In this example, the chip pads 410A of the second semiconductor chip 210 have a similar structure to the chip pads 10A of the first semiconductor chip 10.

The second semiconductor chip 210 is disposed on the first semiconductor device 100B such that an active surface, on which the chip pads 410A are disposed, faces downward.

The conductive bump 220 is located to overlap, or is located on or over, the chip pad 410A. The conductive bump 220 includes a conductive pillar 221 and a solder layer 222. The conductive pillar 221 is disposed under the second semiconductor chip 210. The solder layer 222 is disposed on the lower end of the conductive pillar 221 and is bonded to the bump bonding pad section 22 of the redistribution line 20.

The second semiconductor chip 210 is connected to the first semiconductor device 100B offset in the X direction relative to the first semiconductor chip 10. The bump bonding pad section 22 of the redistribution line 20 of the first semiconductor device 100B is disposed offset in the X direction relative to the chip pad 10A of the first semiconductor chip 10. The arrangement of the chip pads 410A of the second semiconductor chip 210 is similar to the arrangement of the chip pads 10A of the first semiconductor chip 10. The conductive bumps 220 overlap, or are disposed below, the chip pads 410A of the second semiconductor chip 210. As a result, the second semiconductor chip 210 is connected to the first semiconductor device 100B offset in the X direction relative to the first semiconductor chip 10. Accordingly, the second semiconductor chip 210 partially overlaps, or is partially disposed over, the first semiconductor chip 10 in the Z direction.

The molding member 700 is formed to surround the semiconductor devices 100B and 200B and the metal wires 400. The molding member 700 seals the semiconductor devices 100B and 200B and the metal wires 400 to protect the semiconductor devices 100B and 200B and the metal wires 400 from external environments. The first semiconductor device 100B and the second semiconductor device 200B are spaced apart from each other in the Z direction, and the molding member 700 extends between the first semiconductor device 100B and the second semiconductor device 200B. In FIG. 22, the molding member 700 is formed to substantially completely cover the second semiconductor device 200B, although the present application is not limited to this example. The molding member 700 may be formed with a section of a surface of the second semiconductor device 200B exposed.

Although the detailed embodiments are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

1. A semiconductor device comprising:
a chip body having a chip region and a residual scribe lane that surrounds the chip region;
a passivation layer disposed on the chip region of the chip body;
a first dielectric layer disposed on the passivation layer and the residual scribe lane of the chip body;
a redistribution line disposed on the chip region of the first dielectric layer and including a wire bonding pad section; and
a second dielectric layer disposed on the first dielectric layer and the redistribution line and having a first opening through which the wire bonding pad section is exposed.

2. The semiconductor device according to claim 1, wherein the first dielectric layer comprises:
a first section disposed on the passivation layer; and
a second section disposed on the residual scribe lane of the chip body;
wherein the second section is thicker than the first section.

3. The semiconductor device according to claim 1, wherein the first dielectric layer covers the passivation layer and the residual scribe lane of the chip body as a single unbroken layer.

4. The semiconductor device according to claim 1, wherein the first dielectric layer comprises:
a first section disposed on the passivation layer; and
a second section disposed on the residual scribe lane of the chip body;
wherein the second dielectric layer covers the first section of the first dielectric layer and the second section of the first dielectric layer is not covered with the second dielectric layer.

5. The semiconductor device according to claim 1, wherein the first dielectric layer comprises:
a first section disposed on the passivation layer; and
a second section disposed on the residual scribe lane of the chip body;
wherein the second section of the first dielectric layer protrudes beyond an outer periphery of the second dielectric layer.

6. The semiconductor device according to claim 1, wherein the wire bonding pad section of the redistribution line is disposed near an edge of the chip region adjacent to the residual scribe lane.

7. The semiconductor device according to claim 1, wherein the first dielectric layer is disposed between the wire bonding pad section and the passivation layer.

8. The semiconductor device according to claim 1, wherein the first dielectric layer comprises:
a first section disposed on the passivation layer; and
a second section disposed on the residual scribe lane of the chip body,
wherein the first opening is spaced apart from the second section of the first dielectric layer in a first direction.

9. The semiconductor device according to claim 1, wherein the second dielectric layer includes a photosensitive polymer.

10. A semiconductor package comprising:
a first semiconductor device including a chip body having a chip region and a residual scribe lane that surrounds the chip region, a passivation layer disposed on the chip region, a first dielectric layer covering the passivation layer and the residual scribe lane, a redistribution line disposed on the chip region of the first dielectric layer and including a wire bonding pad section and a bump bonding pad section, and a second dielectric layer disposed on the first dielectric layer and the redistribution line and having a first opening through which the wire bonding pad section is exposed and a second opening through which the bump bonding pad section is exposed;
a second semiconductor device including a second semiconductor chip and a conductive bump connected to the second semiconductor chip and stacked on the first semiconductor device such that the conductive bump is bonded to the bump bonding pad section of the redistribution line;
a package substrate including a first substrate pad and supporting the first semiconductor device and the second semiconductor device; and
a metal wire having a first end connected to the first substrate pad and a second end connected to the wire bonding pad section.

11. The semiconductor package according to claim 10, wherein the first dielectric layer comprises:
a first section disposed on the passivation layer; and
a second section disposed on the residual scribe lane of the chip body;
wherein the second section is thicker than the first section.

12. The semiconductor package according to claim 10, wherein the first dielectric layer comprises:
a first section disposed on the passivation layer; and
a second section disposed on the residual scribe lane of the chip body;
wherein the wire bonding pad section is disposed on the first section of the first dielectric layer.

13. The semiconductor package according to claim 10, wherein the first dielectric layer comprises:
a first section disposed on the passivation layer; and
a second section disposed on the residual scribe lane of the chip body;
wherein the first opening is spaced apart from the second section of the first dielectric layer in a first direction.

14. The semiconductor package according to claim 10, wherein the first dielectric layer covers the passivation layer and the residual scribe lane of the chip body as a single unbroken layer.

15. The semiconductor package according to claim 10, further comprising:
a molding member disposed on the package substrate and sealing the first semiconductor device and the second semiconductor device; and
an external connection terminal attached to a second substrate pad of the package substrate.

16. A semiconductor device comprising:
a semiconductor chip including a chip region and a residual scribe lane that surrounds the chip region and having a passivation layer disposed on the chip region;
a first dielectric layer covering the passivation layer and the residual scribe lane;
a redistribution line disposed on the first dielectric layer and including a wire bonding pad section; and
a second dielectric layer disposed on the first dielectric layer and the redistribution line and having a first opening through which the wire bonding pad section is exposed.

17. The semiconductor device according to claim 16, wherein the first dielectric layer comprises:
a first section disposed on the passivation layer; and
a second section disposed on the residual scribe lane;
wherein the second section is thicker than the first section.

18. The semiconductor device according to claim 16, wherein the first dielectric layer is disposed between the wire bonding pad section and the passivation layer.

19. The semiconductor device according to claim 16, wherein the first dielectric layer comprises:
a first section disposed on the passivation layer; and
a second section disposed on the residual scribe lane;
wherein the first opening is spaced apart from the second section of the first dielectric layer in a first direction.
